(19) United States
(12) Patent Application Publication
(10) Pub. No.: US 2026/0117148 A1
(43) Pub. Date: Apr. 30, 2026

(54) SEMICONDUCTOR TREATMENT LIQUID, TREATMENT METHOD FOR OBJECT TO BE TREATED, AND MANUFACTURING METHOD OF ELECTRONIC DEVICE

(71) Applicant: FUJIFILM CORPORATION, Tokyo (JP)

(72) Inventors: Shimpei Yamada, Shizuoka (JP); Tetsuya Kamimura, Shizuoka (JP); Atsushi Mizutani, Shizuoka (JP); Yuta Shigenoi, Shizuoka (JP)

(21) Appl. No.: 19/005,344

(22) Filed: Dec. 30, 2024

Related U.S. Application Data
(63) Continuation of application No. PCT/JP2023/022080, filed on Jun. 14, 2023.

(30) Foreign Application Priority Data
Jul. 13, 2022 (JP) 2022-112421

(51) Int. Cl. C11D 7/32; C11D 7/34; H01L 21/02

(52) U.S. Cl. CPC C11D 7/3281; C11D 7/34; H10P 70/277

(57) ABSTRACT

An object of the present invention is to provide a semiconductor treatment liquid which has excellent anticorrosion properties against at least one metal selected from the group consisting of Cu and Co in a case of being brought into contact with an object containing, and in which defects are less likely to remain on a surface of the object to be treated after the object to be treated is subjected to water cleaning; a treatment method for an object to be treated; and a manufacturing method of an electronic device. The semiconductor treatment liquid of the present invention contains at least one purine compound selected from the group consisting of purine and a purine derivative, at least one specific compound selected from the group consisting of an organic sulfonic acid compound having 10 or less carbon atoms, sulfuric acid, and a salt of these compounds, and water, in which a pH is more than 7.0.

### CROSS-REFERENCE TO RELATED APPLICATIONS

This application is a Continuation of PCT International Application No. PCT/JP2023/022080 filed on Jun. 14, 2023, which claims priority under 35 U.S.C. § 119(a) to Japanese Patent Application No. 2022-112421 filed on Jul. 13, 2022. The above applications are hereby expressly incorporated by reference, in their entirety, into the present application.

### BACKGROUND OF THE INVENTION

### 1. Field of the Invention

The present invention relates to a semiconductor treatment liquid, a treatment method for an object to be treated, and a manufacturing method of an electronic device.

### 2. Description of the Related Art

Semiconductor elements such as a charge-coupled device (CCD) and a memory are manufactured by forming a fine electronic circuit pattern on a substrate using a photolithographic technique. For example, the semiconductor element is manufactured by forming, on a substrate, a resist film on a laminate including a metal film serving as a wiring line material, an etching stop layer, and an interlayer insulating layer, and performing a photolithography step and an etching step.

In addition, in a manufacturing process of the semiconductor element, a chemical mechanical polishing (CMP) treatment in which a surface of a semiconductor substrate having a metal wire film, a barrier metal, an insulating film, or the like is flattened using a polishing slurry containing polishing fine particles (for example, silica and alumina) or the like may be carried out.

In the manufacturing process of the semiconductor element as described above, a method of removing unnecessary metal-containing substances, a resist, residues, and the like on the substrate using a treatment liquid is generally used. Hereinafter, such a treatment liquid used in the manufacturing process of the semiconductor element is also referred to as “semiconductor treatment liquid”.

As the treatment liquid as described above, for example, JP2016-086094A discloses a treatment liquid for a substrate of a semiconductor device, containing (A) a specific compound, (B) at least one compound selected from the group consisting of adenine, purine, guanine, hypoxanthine, xanthine, theobromine, caffeine, uric acid, isoguanine, and derivatives thereof, (C) a pH adjuster, and (D) water, in which a pH is 8 or more.

### SUMMARY OF THE INVENTION

As a performance required for the treatment liquid, in a case where the treatment liquid is applied to an object containing a specific metal (specifically, at least one metal selected from the group consisting of Cu and Co), the treatment liquid has excellent anticorrosion properties against the specific metal, and has a performance in which defects are unlikely to remain on the surface of the object to be treated after the treatment.

As a result of studying characteristics of the treatment liquid specifically disclosed in JP2016-086094A, the present inventors have found that there is a problem in that defects remain on the surface of the object to be treated after bringing the object containing at least one metal selected from the group consisting of Cu and Co into contact with the treatment liquid, and then performing water cleaning.

An object of the present invention is to provide a treatment liquid which has excellent anticorrosion properties against at least one metal selected from the group consisting of Cu and Co in a case of being brought into contact with an object containing, and in which defects are less likely to remain on a surface of the object to be treated after the object to be treated is subjected to water cleaning.

Another object of the present invention is to provide a treatment method for an object to be treated, using the treatment liquid, and a manufacturing method of an electronic device.

The present inventor has conducted intensive studies to achieve the above-described objects, and as a result, they have found that the objects can be achieved by the following configurations.

[1]A semiconductor treatment liquid comprising:
at least one purine compound selected from the group consisting of purine and a purine derivative;
at least one specific compound selected from the group consisting of an organic sulfonic acid compound having 10 or less carbon atoms, sulfuric acid, and a salt of these compounds; and
water,
in which a pH is more than 7.0.

[2] The semiconductor treatment liquid according to [1],
in which the specific compound includes at least one selected from the group consisting of sulfuric acid, methanesulfonic acid, ethanesulfonic acid, 1,2-ethanedisulfonic acid, benzenesulfonic acid, paratoluenesulfonic acid, and a salt of these compounds.

[3] The semiconductor treatment liquid according to [1] or [2],
in which a content of the specific compound is 0.1% to 40.0% by mass with respect to a total mass of components in the treatment liquid excluding a solvent.

[4] The semiconductor treatment liquid according to any one of [1] to [3],
in which a mass ratio of a content of the specific compound to a content of the purine compound is 0.01 to 100.0.

[5] The semiconductor treatment liquid according to any one of [1] to [4],
in which a pKa of the specific compound is 2.0 or less.

[6] The semiconductor treatment liquid according to any one of [1] to [5], further comprising:
an amine compound.

[7] The semiconductor treatment liquid according to [6],
in which the amine compound includes at least one selected from the group consisting of a quaternary ammonium compound and a tertiary amine compound.

[8] The semiconductor treatment liquid according to [6] or [7],
in which the amine compound is a tertiary amine compound.

[9] The semiconductor treatment liquid according to any one of [6] to [8],
in which the amine compound has two or more nitrogen atoms.

[10] The semiconductor treatment liquid according to any one of [6] to [9],
in which the semiconductor treatment liquid contains two or more amine compounds.

[11] The semiconductor treatment liquid according to any one of [1] to [10],
in which the pH is 9.0 to 14.0. [12] The semiconductor treatment liquid according to any one of [1] to [11],
in which the purine compound includes at least one selected from the group consisting of adenine, xanthine, guanine, adenosine, hypoxanthine, and benzyladenine.

[13] The semiconductor treatment liquid according to any one of [1] to [12],
in which the semiconductor treatment liquid is used as a cleaning liquid.

[14] The semiconductor treatment liquid according to any one of [1] to [13],
in which the semiconductor treatment liquid is used for an object which has been subjected to a chemical mechanical polishing treatment.

[15] The semiconductor treatment liquid according to any one of [1] to [14],
in which the semiconductor treatment liquid is used for an object containing at least one metal selected from the group consisting of Cu and Co.

[16] The semiconductor treatment liquid according to any one of [1] to [15],
in which the semiconductor treatment liquid is used for an object containing at least one metal selected from the group consisting of Cu and Co, which has been subjected to a chemical mechanical polishing treatment.

[17]A treatment method for an object to be treated, comprising:
a step of bringing an object containing at least one metal selected from the group consisting of Cu and Co, which has been subjected to a chemical mechanical polishing treatment, into contact with the semiconductor treatment liquid according to any one of [1] to [16].

[18]A manufacturing method of an electronic device, comprising:
the treatment method for an object to be treated according to [17].

According to the present invention, it is possible to provide a treatment liquid which has excellent anticorrosion properties against at least one metal selected from the group consisting of Cu and Co in a case of being brought into contact with an object containing, and in which defects are less likely to remain on a surface of the object to be treated after the object to be treated is subjected to water cleaning.

In addition, according to the present invention, it is possible to provide a treatment method for an object to be treated, using the treatment liquid, and a manufacturing method of an electronic device.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

In the present specification, numerical ranges represented by “to” include numerical values before and after “to” as lower limit values and upper limit values.

In addition, in the present specification, in a case where there are two or more components corresponding to a certain component, “content” of such a component means the total content of the two or more components.

In the present specification, “total mass of components in the treatment liquid excluding a solvent” means the total mass of all components contained in the treatment liquid other than a solvent such as water and an organic solvent.

In the present specification, in a case of a plurality of substituents, linking groups, and the like (hereinafter, referred to as a substituent and the like) represented by specific reference numeral, or in a case of simultaneously defining a plurality of the substituent and the like, it means that each of the substituent and the like may be the same as or different with each other. The same applies to the definition of the number of substituents and the like.

A bonding direction of divalent groups cited in the present specification is not limited unless otherwise specified. For example, in a case where Y in a compound represented by Formula “X—Y-Z” is —COO—, Y may be —CO—O— or —O—CO—. In addition, the above-described compound may be “X—CO—O—Z” or “X—O—CO—Z”.

In the present specification, “ppm” means “parts-per-million (106)”, and “ppb” means “parts-per-billion (10⁻⁹)”.

In the present specification, “weight-average molecular weight” means a weight-average molecular weight in terms of polyethylene glycol measured by gel permeation chromatography (GPC).

### [Treatment Liquid]

Hereinafter, each component contained in the semiconductor treatment liquid according to the embodiment of the present invention will be described in detail.

The semiconductor treatment liquid (hereinafter, simply referred to as “treatment liquid”) according to the embodiment of the present invention contains at least one purine compound selected from the group consisting of purine and a purine derivative, at least one specific compound selected from the group consisting of an organic sulfonic acid compound having 10 or less carbon atoms and sulfuric acid, and water, in which a pH is more than 7.0.

The reason why the treatment liquid having the above-described configuration can achieve the object of the present invention is not necessarily clear, but the present inventors speculate as follows.

The mechanism by which the effect is obtained is not limited by the following supposition. In other words, even in a case where an effect is obtained by a mechanism other than the following, it is included in the scope of the present invention.

Since the treatment liquid exhibits a pH of more than 7.0, the treatment liquid has excellent removability of residues. In addition, the purine compound in the treatment liquid interacts with a predetermined metal contained in the object to exhibit excellent anticorrosion properties against the predetermined metal. On the other hand, the above-described purine compound may remain on the surface of the object to be treated after the treatment, and may cause an increase in the number of defects. It is considered that, by further containing a predetermined specific compound in the treatment liquid, as a result of interaction between the purine compound remaining on the object to be treated after the treatment liquid is brought into contact with the object to be treated, and the specific compound, purine compound-derived defects can be efficiently removed from the surface of the object to be treated in a case where the object to be treated is subjected to water cleaning. As a result, it is presumed that the anticorrosion properties against the predetermined metal are excellent and defects are unlikely to remain on the surface of the object to be treated after the treatment.

Hereinafter, in the present specification, the characteristic in which defects are unlikely to remain on the surface of the object to be treated after bringing the treatment liquid into contact with the object and further performing water cleaning on the object to be treated is also referred to as “defect removability”. In addition, the fact that at least one of the anticorrosion properties or the defect removability is more excellent is also referred to as “effect of the present invention is more excellent”.

### [Purine Compound]

The treatment liquid contains at least one purine compound selected from the group consisting of purine and a purine derivative.

The purine compound preferably includes at least one selected from the group consisting of compounds represented by Formulae (A1) to (A4); more preferably includes at least one selected from the group consisting of a compound represented by Formula (A1) and compounds represented by Formulae (A4) to (A7); still more preferably includes at least one selected from the group consisting of a compound represented by Formula (A1), a compound represented by Formula (A5), and a compound represented by Formula (A4), in which at least one of R¹² to R¹⁴ is a hydrogen atom; and particularly preferably includes at least one selected from the group consisting of a compound represented by Formula (A1), in which R¹ is an amino group and R³ is a hydrogen atom, and a compound represented by Formula (A4), in which at least one of R¹² to R¹⁴ is a hydrogen atom.

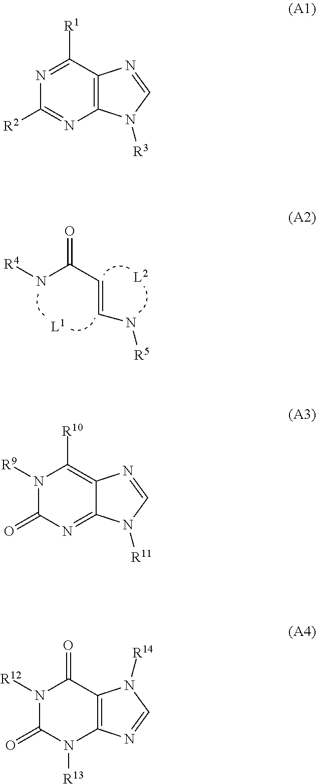

In Formula (A1), R¹ to R³ each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

The above-described alkyl group may be linear, branched, or cyclic.

The number of carbon atoms in the above-described alkyl group is preferably 1 to 10, more preferably 1 to 5, and still more preferably 1 to 3.

Examples of the above-described sugar group include a group obtained by removing one hydroxy group from a sugar selected from the group consisting of a monosaccharide, a disaccharide, and a polysaccharide; and a group obtained by removing one hydroxy group from a monosaccharide is preferable.

Examples of the monosaccharides include a pentose such as ribose, deoxyribose, arabinose, or xylose, a triose, a tetrose, a hexose, and a heptose; and a pentose is preferable, ribose, deoxyribose, arabinose, or xylose is more preferable, and ribose or deoxyribose is still more preferable.

Examples of the disaccharides include sucrose, lactose, maltose, trehalose, turanose, and cellobiose.

Examples of the polysaccharides include glycogen, starch, and cellulose.

The above-described saccharides may be chain-like or cyclic, and are preferably cyclic.

Examples of the above-described cyclic saccharides include a furanose ring and a pyranose ring.

The polyoxyalkylene group-containing group which may have a substituent means a group containing, as a part of the group, a polyoxyalkylene group, which may have a substituent.

Examples of the polyoxyalkylene group constituting the polyoxyalkylene group-containing group include a polyoxyethylene group, a polyoxypropylene group, and a polyoxybutylene group; and a polyoxyethylene group is preferable.

Examples of the substituent contained in the alkyl group, amino group, sugar group, and polyoxyalkylene group-containing group described above include a hydrocarbon group such as an alkyl groug, an aryl group, and a benzyl group; a halogen atom such as a fluorine atom, a chlorine atom, and a bromine atom; an alkoxy group; a hydroxy group; an alkoxycarbonyl group such as a methoxycarbonyl group and an ethoxycarbonyl group; an acyl group such as an acetyl group, a propionyl group, and a benzoyl group; a cyano group; and a nitro group.

R¹ is preferably a hydrogen atom or an amino group which may have a substituent, and more preferably an amino group which may have a substituent.

Another suitable aspect of R¹ is preferably an alkyl group which may have a substituent, a thiol group, a hydroxy group, a halogen atom, a sugar group which may have a substituent, or a polyoxyalkylene group-containing group which may have a substituent.

R² is preferably a hydrogen atom or an alkyl group which may have a substituent, and more preferably a hydrogen atom.

R³ is preferably a hydrogen atom, an alkyl group which may have a substituent, or a sugar group which may have a substituent, more preferably a hydrogen atom or a sugar group which may have a substituent, and still more preferably a hydrogen atom.

In Formula (A2), L^{I} represents —CR⁶═N— or —C(═O)—NR⁷—, L² represents —N═CH— or —NR⁸—C(═O)—, and R⁴ to R⁸ each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

Examples of an aspect of each group represented by R⁴ to R¹ include the above-described aspect of each group represented by R¹ to R³ in Formula (A1).

R⁴ and R⁵ are preferably a hydrogen atom or an alkyl group which may have a substituent, and more preferably a hydrogen atom.

R⁶ is preferably a hydrogen atom, an alkyl group which may have a substituent, or an amino group which may have a substituent, and more preferably a hydrogen atom or an amino group which may have a substituent.

R⁷ is preferably a hydrogen atom or an alkyl group which may have a substituent, and more preferably a hydrogen atom.

L² is preferably —N═CH—.

R¹ is preferably a hydrogen atom or an alkyl group which may have a substituent, and more preferably a hydrogen atom.

In Formula (A3), R⁹ to R¹¹ each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

Examples of an aspect of each group represented by R⁹ to R¹¹ include the above-described aspect of each group represented by R¹ to R³ in Formula (A1).

R⁹ is preferably a hydrogen atom or an alkyl group which may have a substituent, and more preferably a hydrogen atom.

R¹⁰ is preferably a hydrogen atom, an alkyl group which may have a substituent, or an amino group which may have a substituent, more preferably a hydrogen atom or an amino group which may have a substituent, and still more preferably an amino group which may have a substituent.

R¹¹ is preferably a hydrogen atom or an alkyl group which may have a substituent, and more preferably a hydrogen atom.

In Formula (A4), R¹² to R¹⁴ each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

Examples of an aspect of each group represented by R¹² to R¹⁴ include the above-described aspect of each group represented by R¹ to R³ in Formula (A1).

R¹² is preferably a hydrogen atom or an alkyl group which may have a substituent, and more preferably a hydrogen atom.

Another suitable aspect of R¹² is preferably an alkyl group which may have a substituent, an amino group which may have a substituent, a thiol group, a hydroxy group, a halogen atom, a sugar group which may have a substituent, or a polyoxyalkylene group-containing group which may have a substituent.

R¹³ is preferably a hydrogen atom or an alkyl group which may have a substituent, and more preferably a hydrogen atom.

R¹⁴ is preferably a hydrogen atom or an alkyl group which may have a substituent, and more preferably a hydrogen atom.

It is preferable that at least one of R¹² to R¹⁴ is a hydrogen atom.

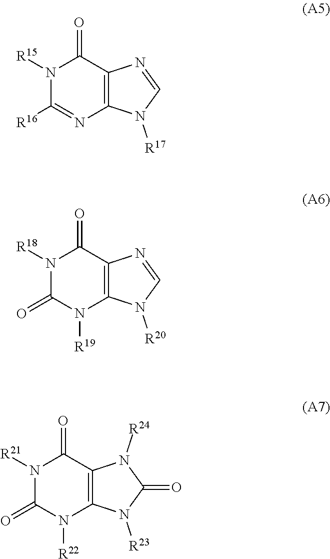

In Formula (A5), R¹⁵ to R¹⁷ each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

Examples of an aspect of each group represented by R¹⁵ to R¹⁷ include the above-described aspect of each group represented by R¹ to R³ in Formula (A1).

R¹⁵ is preferably a hydrogen atom or an alkyl group which may have a substituent, and more preferably a hydrogen atom.

R¹⁶ is preferably a hydrogen atom, an alkyl group which may have a substituent, or an amino group which may have a substituent, more preferably a hydrogen atom or an amino group which may have a substituent, and still more preferably a hydrogen atom.

Another suitable aspect of R¹⁶ is preferably a hydrogen atom, an alkyl group which may have a substituent, a thiol group, a hydroxy group, a halogen atom, a sugar group which may have a substituent, or a polyoxyalkylene group-containing group which may have a substituent.

R¹⁷ is preferably a hydrogen atom or an alkyl group which may have a substituent, and more preferably a hydrogen atom.

In Formula (A6), R¹⁸ to R²⁰ each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

Examples of an aspect of each group represented by R¹⁸ to R²⁰ include the above-described aspect of each group represented by R¹ to R³ in Formula (A1).

R¹⁸ to R²⁰ are preferably a hydrogen atom or an alkyl group which may have a substituent, and more preferably a hydrogen atom.

In Formula (A7), R²¹ to R²⁴ each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

Examples of an aspect of each group represented by R²¹ to R²⁴ include the above-described aspect of each group represented by R¹ to R³ in Formula (A1).

R²¹ to R²⁴ are preferably a hydrogen atom or an alkyl group which may have a substituent, and more preferably a hydrogen atom.

Examples of the purine compound include purine, adenine, guanine, hypoxanthine, xanthine, theobromine, caffeine, uric acid, isoguanine, adenosine, enprofylline, theophylline, xanthosine, 7-methylxanthosine, 7-methylxanthine, eritadenine, 3-methylxanthine, 3-methylxanthine, 1,7-dimethylxanthine, 1-methylxanthine, 1,3-dipropyl-7-methylxanthine, 3,7-dihydro-7-methyl-1H-purine-2,6-dione, 1,7-dipropyl-3-methylxanthine, 1-methyl-3,7-dipropylxanthine, 1,3-dipropyl-7-methyl-8-dicyclopropylmethylxanthine, 1,3-dibutyl-7-(2-oxopropyl)xanthine, 1-butyl-3,7-dimethylxanthine, 3,7-dimethyl-1-propylxanthine, mercaptopurine, 2-aminopurine, 6-aminopurine, 6-benzylaminopurine (benzyladenine), nelarabine, vidarabine, 2,6-dichloropurine, aciclovir, N6-benzoyladenosine, trans-zeatin, entecavir, valaciclovir, abacavir, 2′-deoxyguanosine, disodium inosinate, ganciclovir, guanosine 5′-disodium monophosphate, O-cyclohexylmethylguanine, N2-isobutyryl-2′-deoxyguanosine, P-nicotinamide adenine dinucleotide phosphate, 6-chloro-9-(tetrahydropyran-2-yl)purine, clofarabine, kinetin, 7-(2,3-dihydroxypropyl)theophylline, 6-mercaptopurine, proxyphylline, 2,6-diaminopurine, 2′,3′-dideoxyinosine, theophylline-7-acetic acid, 2-chloroadenine, 2-amino-6-chloropurine, 8-bromo-3-methylxanthine, 2-fluoroadenine, penciclovir, 9-(2-hydroxyethyl)adenine, 7-(2-chloroethyl)theophylline, 2-amino-6-iodopurine, 2-thioxanthine, 2-amino-6-methoxypurine, N-acetylguanine, adefovir dipivoxil, 8-chlorotheophylline, 6-methoxypurine, 1-(3-chloropropyl)theobromine, 6-(dimethylamino)purine, and inosine.

Among these, the purine compound preferably includes at least one selected from the group consisting of purine, adenine, guanine, hypoxanthine, xanthine, theobromine, caffeine, isoguanine, adenosine, enprofylline, xanthosine, 7-methylxanthosine, 7-methylxanthine, theophylline, eritadenine, paraxanthine, benzyladenine, 3-methyladenine, 3-methylxanthine, 1,7-dimethylxanthine, and 1-methylxanthine; more preferably includes at least one selected from the group consisting of adenine, guanine, hypoxanthine, xanthine, adenosine, and benzyladenine; and particularly preferably includes at least one selected from the group consisting of adenine and xanthine.

The purine compound may be used alone or in combination of two or more thereof.

From the viewpoint that the effect of the present invention is more excellent, a content of the purine compound is preferably 0.00005% to 0.25% by mass, more preferably 0.0001% to 0.01% by mass, still more preferably 0.0001% to 0.008% by mass, and particularly preferably 0.0002% to 0.003% by mass with respect to the total mass of the treatment liquid.

From the viewpoint that the effect of the present invention is more excellent, the content of the purine compound is preferably 0.01% to 30.0% by mass, more preferably 0.05% to 20.0% by mass, and still more preferably 0.1% to 10.0% by mass with respect to the total mass of components in the treatment liquid excluding a solvent.

### [Specific Compound]

The treatment liquid contains the specific compound.

The specific compound is at least one compound selected from the group consisting of an organic sulfonic acid compound having 10 or less carbon atoms, sulfuric acid, and a salt thereof.

The organic sulfonic acid compound having 10 or less carbon atoms is an organic compound having a sulfonic acid group.

The number of sulfonic acid groups included in the organic sulfonic acid compound having 10 or less carbon atoms is not particularly limited, but is preferably 1 to 5, more preferably 1 to 3, and still more preferably 1.

The number of carbon atoms in the above-described organic sulfonic acid compound is 10 or less, and from the viewpoint that the effect of the present invention is more excellent, it is preferably 8 or less, and more preferably 7 or less. The lower limit thereof is not particularly limited, but is 1 or more.

The salt of the organic sulfonic acid compound having 10 or less carbon atoms means a compound in which a hydrogen ion of the sulfonic acid group in the above-described organic sulfonic acid compound is substituted with another cation (an inorganic cation or an organic cation). Examples of the inorganic cation include each cation of an alkali metal (for example, lithium, sodium, potassium, or the like), and ammonium (NH₄⁺). Examples of the organic cation include a tetraalkylammonium ion.

As the organic sulfonic acid compound having 10 or less carbon atoms, a compound represented by Formula (B) is preferable.

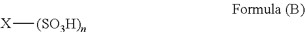

In Formula (B), n represents 1 or 2; X represents an alkyl group which may have a substituent or an aryl group which may have a substituent in a case where n represents 1, and X represents an alkylene group which may have a substituent or an arylene group which may have a substituent in a case where n represents 2. However, the number of carbon atoms in the alkyl group which may have a substituent, in the aryl group which may have a substituent, in the alkylene group which may have a substituent, and in the arylene group which may have a substituent is 10 or less.

The alkyl group which may have a substituent, represented by X, may be linear, branched, or cyclic.

The number of carbon atoms in the above-described alkyl group which may have a substituent is 10 or less, preferably 1 to 8, more preferably 1 to 7, and still more preferably 1 to 3. In a case where the alkyl group does not have a substituent, the above-described number of carbon atoms in the above-described alkyl group which may have a substituent means the number of carbon atoms in the alkyl group itself; and in a case where the alkyl group has a substituent, the above-described number of carbon atoms in the above-described alkyl group which may have a substituent means the number of carbon atoms in the entire alkyl group having a substituent. For example, in a case where the alkyl group has a carboxy group as the substituent, the above-described number of carbon atoms in the above-described alkyl group which may have a substituent means that the total number of carbon atoms in the carboxy group and the alkyl group is 10 or less.

Examples of the substituent contained in the above-described alkyl group include an aryl group, a hydroxy group, a carboxy group, an amino group, and a halogen atom.

The aryl group which may have a substituent, represented by X, may have either a monocyclic structure or a polycyclic structure, and is preferably a phenyl group which may have a substituent.

The number of carbon atoms in the above-described aryl group which may have a substituent is 10 or less, preferably 6 to 10, more preferably 6 to 8, and still more preferably 6 or 7. In a case where the aryl group does not have a substituent, the above-described number of carbon atoms in the above-described aryl group which may have a substituent means the number of carbon atoms in the aryl group itself; and in a case where the aryl group has a substituent, the above-described number of carbon atoms in the above-described aryl group which may have a substituent means the number of carbon atoms in the entire aryl group having a substituent. For example, in a case where the aryl group has an alkyl group as the substituent, the above-described number of carbon atoms in the above-described aryl group which may have a substituent means that the total number of carbon atoms in the alkyl group and the aryl group is 10 or less.

Examples of the substituent contained in the above-described aryl group include an alkyl group, a hydroxy group, a carboxy group, an amino group, and a halogen atom.

The alkylene group which may have a substituent, represented by X, may be linear, branched, or cyclic.

The number of carbon atoms in the above-described alkylene group which may have a substituent is 10 or less, preferably 1 to 8, more preferably 1 to 7, and still more preferably 1 to 3. In a case where the alkylene group does not have a substituent, the above-described number of carbon atoms in the above-described alkylene group which may have a substituent means the number of carbon atoms in the alkylene group itself; and in a case where the alkylene group has a substituent, the above-described number of carbon atoms in the above-described alkylene group which may have a substituent means the number of carbon atoms in the entire alkylene group having a substituent. For example, in a case where the alkylene group has a carboxy group as the substituent, the above-described number of carbon atoms in the above-described alkylene group which may have a substituent means that the total number of carbon atoms in the carboxy group and the alkylene group is 10 or less.

Examples of the substituent contained in the above-described alkylene group include an aryl group, a hydroxy group, a carboxy group, an amino group, and a halogen atom.

The arylene group which may have a substituent, represented by X, may be monocyclic or polycyclic.

The number of carbon atoms in the above-described arylene group which may have a substituent is 10 or less, preferably 6 to 10, more preferably 6 to 8, and still more preferably 6 or 7. In a case where the arylene group does not have a substituent, the above-described number of carbon atoms in the above-described arylene group which may have a substituent means the number of carbon atoms in the arylene group itself; and in a case where the arylene group has a substituent, the above-described number of carbon atoms in the above-described arylene group which may have a substituent means the number of carbon atoms in the entire arylene group having a substituent. For example, in a case where the arylene group has an alkyl group as the substituent, the above-described number of carbon atoms in the above-described arylene group which may have a substituent means that the total number of carbon atoms in the alkyl group and the arylene group is 10 or less.

Examples of the substituent contained in the above-described arylene group include an alkyl group, a hydroxy group, a carboxy group, an amino group, and a halogen atom.

In a case where n is 1, from the viewpoint that the effect of the present invention is more excellent, X is preferably an unsubstituted alkyl group or a phenyl group which may have an alkyl group. However, the number of carbon atoms in the above-described unsubstituted alkyl group is 10 or less, preferably 1 to 8, more preferably 1 to 7, and still more preferably 1 to 3. The number of carbon atoms in the above-described phenyl group which may have an alkyl group is 10 or less, preferably 6 to 10, more preferably 6 to 8, and still more preferably 6 or 7. In a case where the phenyl group does not have an alkyl group, the above-described number of carbon atoms in the above-described phenyl group which may have an alkyl group means the number of carbon atoms in the phenyl group itself; and in a case where the phenyl group has an alkyl group, the above-described number of carbon atoms in the above-described phenyl group which may have an alkyl group means the number of carbon atoms in the entire phenyl group having an alkyl group. For example, in a case where the compound represented by Formula (B) is paratoluenesulfonic acid, n is 1, X corresponds to a phenyl group having a methyl group, and the number of carbon atoms in X is calculated to be 7.

In a case where n is 2, from the viewpoint that the effect of the present invention is more excellent, X is preferably an unsubstituted alkylene group. However, the number of carbon atoms in the above-described unsubstituted alkylene group is 10 or less.

The sulfuric acid is a compound represented by H₂SO₄.

The salt of the sulfuric acid (sulfate) is an inorganic compound containing a sulfate ion (SO₄²⁻).

Examples of the specific compound include sulfuric acid, methanesulfonic acid, ethanesulfonic acid, 1,2-ethanedithiol, benzenesulfonic acid, paratoluenesulfonic acid, naphthalenesulfonic acid, camphor sulfonic acid, and a salt thereof; and sulfuric acid, methanesulfonic acid, ethanesulfonic acid, 1,2-ethanedithiol, benzenesulfonic acid, paratoluenesulfonic acid, or a salt thereof is preferable, and sulfuric acid, methanesulfonic acid, or paratoluenesulfonic acid is more preferable.

A pKa of the specific compound is preferably −10.0 to 2.0, more preferably −7.0 to 1.0, and still more preferably −6.0 to −0.5.

The above-described pKa is a value calculated using “ACD/Pka DB Ver 8.0” (manufactured by ACD/Labs, Advanced Chemistry Development, Inc.).

In a case where the specific compound has two or more pKa's, it is sufficient that a pKa having the smallest value is within the above-described range.

The specific compound may be used alone or in combination of two or more thereof.

From the viewpoint that the effect of the present invention is more excellent, a content of the specific compound is 0.0001% to 0.50% by mass, more preferably 0.0001% to 0.015% by mass, and still more preferably 0.001% to 0.01% by mass with respect to the total mass of the treatment liquid.

From the viewpoint that the effect of the present invention is more excellent, the content of the specific compound is preferably 0.1% to 40.0% by mass, more preferably 0.5% to 20.0% by mass, and still more preferably 0.8% to 15.0% by mass with respect to the total mass of components in the treatment liquid excluding a solvent.

From the viewpoint that the effect of the present invention is more excellent, a mass ratio of the content of the specific compound to the above-described content of the purine compound (content of specific compound/content of purine compound) is preferably 0.01 to 100.0, more preferably 0.5 to 50.0, still more preferably 0.5 to 20.0, and particularly preferably 1.0 to 10.0.

From the viewpoint that the effect of the present invention is more excellent, a proportion of the total content of an organic sulfonic acid sulfuric acid having 8 or less carbon atoms and sulfuric acid to the total mass of the specific compound is preferably 50% to 100% by mass, more preferably 60% to 100% by mass, and still more preferably 80% to 100% by mass.

### [Water]

The treatment liquid contains water.

The water contained in the treatment liquid is not particularly limited, but from the viewpoint of not affecting the object, distilled water, deionized (DI) water, pure water, or ultrapure water is preferable, and pure water or ultrapure water is more preferable.

A content of water may be a remainder of components which can be contained in the treatment liquid.

The content of the water is preferably 1.0% by mass or more, more preferably 30.0% by mass or more, still more preferably 60.0% by mass or more, and particularly preferably 80.0% by mass or more with respect to the total mass of the treatment liquid. The upper limit thereof is preferably 99.99% by mass or less, more preferably 99.96% by mass or less, still more preferably 99.0% by mass or less, and particularly preferably 97.0% by mass or less with respect to the total mass of the treatment liquid.

The treatment liquid may contain other components in addition to the above-described components (the purine compound, the specific compound, and the water).

Hereinafter, other components will be described in detail.

### [Amine Compound]

The treatment liquid may contain an amine compound.

Examples of the amine compound include a primary amine compound having a primary amino group (—NH₂) in the molecule, a secondary amine compound having a secondary amino group (>NH) in the molecule, a tertiary amine compound having a tertiary amino group (>N—) in the molecule, a quaternary ammonium compound having a quaternary ammonium cation in the molecule, and salts thereof. Furthermore, in a case where the compound has amino groups of different classes, it is classified into the highest amine compound.

The amine compound is a compound different from the above-described purine compound, and the purine compound is not included in the amine compound.

In addition, these amine compounds can also function as a pH adjuster.

The amine compound may have two or more groups selected from the group consisting of a primary amino group to a tertiary amino group and a quaternary ammonium base. That is, the amine compound may be a diamine compound or a polyamine compound.

The amine compound may have a substituent other than the primary amino group to the tertiary amino group and the quaternary ammonium base. Examples of the substituent include a hydroxy group. For example, the treatment liquid may contain an amine compound which may have a hydroxy group.

From the viewpoint that the effect of the present invention is more excellent, the amine compound preferably contains two or more nitrogen atoms.

In a case where the amine compound includes at least one compound selected from the group consisting of a tertiary amine compound and a quaternary ammonium compound, from the viewpoint that the effect of the present invention is more excellent, a molecular weight of the compound selected from the group consisting of a tertiary amine compound and a quaternary ammonium compound is preferably 90 to 500, more preferably 100 to 300, and still more preferably 110 to 200.

The amine compound preferably includes at least one compound selected from the group consisting of a quaternary ammonium compound and a tertiary amine compound, and more preferably includes a tertiary amine compound.

### <Quaternary Ammonium Compound>

The quaternary ammonium compound is preferably a compound having a quaternary ammonium cation in which a nitrogen atom is substituted with four hydrocarbon groups (preferably, alkyl groups). In addition, the quaternary ammonium compound may be a compound having a quaternary ammonium cation in which a nitrogen atom in a pyridine ring is bonded to a substituent (a hydrocarbon group such as an alkyl group and an aryl group), for example, an alkyl pyridinium.

Examples of the quaternary ammonium compound include a quaternary ammonium hydroxide, a quaternary ammonium acetate, and a quaternary ammonium carbonate.

The quaternary ammonium compound is preferably a compound represented by Formula (C).

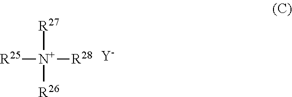

In Formula (C), R²¹ to R²⁸ each independently represent a hydrocarbon group which may have a substituent, and Y⁻ represents an anion.

R²¹ to R²⁸ each independently represent a hydrocarbon group which may have a substituent.

The number of carbon atoms in the above-described hydrocarbon group is preferably 1 to 20, more preferably 1 to 10, and still more preferably 1 to 5.

Examples of the above-described hydrocarbon group include an alkyl group which may have a substituent, an alkenyl group which may have a substituent, an alkynyl group which may have a substituent, an aryl group which may have a substituent, and a group obtained by combining these groups; and an alkyl group which may have a substituent is preferable.

Examples of the substituent included in the above-described hydrocarbon group include a halogen atom such as a fluorine atom, a chlorine atom, and a bromine atom, an alkoxy group, a hydroxy group, an alkoxycarbonyl group such as a methoxycarbonyl group and an ethoxycarbonyl group, an acyl group such as an acetyl group, a propionyl group, and benzoyl group, a cyano group, and a nitro group; and a hydroxy group is preferable.

The number of substituents included in the above-described hydrocarbon group is preferably 1 to 3, and more preferably 1.

The alkyl group, alkenyl group, and alkynyl group described above may be linear, branched, or cyclic. The number of carbon atoms in the alkyl group, the alkenyl group, and the alkynyl group described above is preferably 1 to 20, more preferably 1 to 10, still more preferably 1 to 5, and particularly preferably 1 to 3.

Examples of the substituent contained in the alkyl group, the alkenyl group, and the alkynyl group described above include the substituent contained in the hydrocarbon group described above.

The above-described alkyl group is preferably an unsubstituted alkyl group or a hydroxyalkyl group; more preferably a methyl group, an ethyl group, a propyl group, a butyl group, or a 2-hydroxyethyl group; and still preferably a methyl group, an ethyl group, or a 2-hydroxyethyl group.

The above-described aryl group may be monocyclic or polycyclic.

The number of carbon atoms in the above-described aryl group is preferably 6 to 20, more preferably 6 to 10, and still more preferably 6 to 8.

Examples of the substituent contained in the above-described aryl group include a halogen atom such as a chlorine atom, an alkyl group having 1 to 10 carbon atoms, an alkoxy group having 1 to 10 carbon atoms, a cycloalkoxy group having 3 to 10 carbon atoms, a nitro group, a thiol group, and a dioxirane-yl group; and a halogen atom or an alkyl group having 1 to 10 carbon atoms is preferable, an alkyl group having 1 to 10 carbon atoms is more preferable, and an alkyl group having 1 to 3 carbon atoms is still more preferable.

The number of substituents contained in the above-described aryl group is preferably 1 to 5, more preferably 1 to 3, and still more preferably 1.

Examples of the above-described aryl group include a benzyl group, a phenyl group, a naphthyl group, an anthryl group, a phenanthryl group, an indenyl group, an acenaphthenyl group, a fluorenyl group, and a pyrenyl group; and a benzyl group or a phenyl group is preferable, and a benzyl group is more preferable.

It is preferable that three of R²¹ to R²⁸ represent the same group. For example, it is preferable that R²¹ to R²⁷ represent a 2-hydroxyethyl group and R²⁸ represents a methyl group.

However, from the viewpoint that the effect of the present invention is more excellent, it is preferable to exclude a case in which all of R²¹ to R²⁸ are methyl groups. In other words, it is preferable that the compound represented by Formula (C) does not include a tetramethylammonium salt. That is, it is preferable that the amine compound does not include a tetramethylammonium salt.

Y⁻ represents an anion.

Examples of the anion include acid anions such as a carboxylate ion, a phosphate ion, a phosphonate ion, and a nitrate ion, and a hydroxide ion; and a hydroxide ion is preferable.

Examples of the quaternary ammonium compound include tris(2-hydroxyethyl)methylammonium hydroxide (THEMAH), dimethylbis(2-hydroxyethyl)ammonium hydroxide, tetramethylammonium hydroxide (TMAH), ethyltrimethylammonium hydroxide (ETMAH), trimethylethylammonium hydroxide (TMEAH), dimethyldiethylammonium hydroxide (DMDEAH), methyltriethylammonium hydroxide (MTEAH), tetraethylammonium hydroxide (TEAH), tetrapropylammonium hydroxide (TPAH), tetrabutylammonium hydroxide (TBAH), 2-hydroxyethyltrimethylammonium hydroxide (choline), bis(2-hydroxyethyl)dimethylammonium hydroxide, tri(2-hydroxyethyl)methylammonium hydroxide, tetra(2-hydroxyethyl)ammonium hydroxide, benzyltrimethylammonium hydroxide (BTMAH), and cetyltrimethylammonium hydroxide; and THEMAH, ETMAH, choline, or TEAH is preferable.

### <Tertiary Amine Compound>

The tertiary amine compound is a compound having at least one tertiary amino group (>N—) in a molecule.

The tertiary amine compound may have two or more tertiary amino groups in the molecule, and preferably has two or three tertiary amino groups.

The tertiary amine compound may have a hydroxy group as a substituent.

Examples of the tertiary amino compound having a hydroxy group include N-methyldiethanolamine (MDEA), 2-(dimethylamino)ethanol (DMAE), 2-(diethylamino)ethanol, N-ethyldiethanolamine (EDEA), 2-dimethylamino-2-methyl-1-propanol (DMAMP), 2-(dibutylamino)ethanol, 2-[2-(dimethylamino)ethoxy]ethanol, 2-[2-(diethylamino)ethoxy]ethanol, triethanolamine, and N-butyldiethanolamine (BDEA); and DMAE, EDEA, 2-(diethylamino)ethanol, or DMAMP is preferable, and DMAMP is more preferable.

Examples of the tertiary amino compound having no hydroxy group include an alkylamine such as trimethylamine and triethylamine, an alkylenediamine such as 1-methylpiperazine, 1-(2-hydroxyethyl)piperazine (HEP), 1,4-dimethylpiperazine, 1,4-diazabicyclo[2.2.2]octane (DABCO), and 1,3-bis(dimethylamino)butane, and a polyalkylpolyamine such as 1,3-bis(dimethylamino)butane, N,N,N′,N′-tetramethyl-1,3-propanediamine, and N,N,N′,N″,N″-pentamethyldiethylenetriamine (PMDETA); and an alkylenediamine or a polyalkylpolyamine is preferable, and a polyalkylpolyamine is more preferable.

Among these, PMDETA is preferable as the polyalkylpolyamine.

As the tertiary amine compound, DMAE, EDEA, 2-diethylaminoethanol, DMAMP, or PMDETA is preferable, and DMAMP or PMDETA is more preferable.

### <Other Amine Compounds>

Examples of other amine compounds include a primary amine compound and a secondary amine compound.

The primary amine compound and the secondary amine compound are each a compound having at least one primary amino group or one secondary amino group in the molecule.

The other amine compounds may have a hydroxy group as a substituent.

Examples of the other amine compounds having a hydroxy group include monoethanolamine (MEA), uracil, 2-amino-2-methyl-1-propanol (AMP), N-methyl-2-amino-2-methyl-propanol (MAMP), 2-(2-aminoethylamino)ethanol (AAE), 3-amino-1-propanol, 1-amino-2-propanol, N,N′-bis(2-hydroxyethyl)ethylenediamine, trishydroxymethylaminomethane, diethylene glycolamine (DEGA), 2-(aminoethoxy)ethanol (AEE), N-methylethanolamine, 2-(ethylamino)ethanol, 2-[(hydroxymethyl)amino]ethanol, 2-(propylamino)ethanol, diethanolamine, N-butylethanolamine, and N-cyclohexylethanolamine; and AMP, MAMP, or diethanolamine is preferable, and AMP or MAMP is more preferable.

Examples of the other amine compounds having no hydroxy group include an alkylene amine such as piperazine, 2,5-dimethylpiperazine, ethylenediamine (EDA), 1,3-propanediamine (PDA), 1,2-propanediamine, 1,3-butanediamine, and 1,4-butanediamine, and a polyalkylpolyamine such as diethylenetriamine (DETA), triethylenetetramine (TETA), and tetraethylenepentamine; and a polyalkylpolyamine is preferable.

The amine compound may be used alone or in combination of two or more thereof. From the viewpoint that the effect of the present invention is more excellent, it is preferable that two or more kinds of amine compounds are used in combination.

In a case where two or more kinds of amine compounds are used in combination, it is preferable that at least one kind of the amine compounds is a tertiary amine compound.

From the viewpoint that the effect of the present invention is more excellent, a content of the amine compound is 0.001% to 50% by mass, more preferably 0.005% to 20% by mass, and still more preferably 0.01% to 10% by mass with respect to the total mass of the treatment liquid.

From the viewpoint that the effect of the present invention is more excellent, the content of the amine compound is preferably 30.0% to 99.5% by mass, more preferably 50.0% to 98.0% by mass, and still more preferably 65.0% to 97.0% by mass with respect to the total mass of components in the treatment liquid excluding a solvent.

From the viewpoint that the effect of the present invention is more excellent, a mass ratio of the content of the specific compound to the content of the amine compound (content of specific compound/content of amine compound) is preferably 0.001 to 2.0, more preferably 0.01 to 0.40, and still more preferably 0.02 to 0.20.

From the viewpoint that the effect of the present invention is more excellent, a mass ratio of the content of the amine compound to the content of the purine compound (content of amine compound/content of purine compound) is preferably 0.1 to 1000.0, more preferably 7.5 to 750.0, and still more preferably 20.0 to 150.0.

### [pH Adjuster]

The treatment liquid may contain a pH adjuster to adjust and maintain the pH of the treatment liquid.

The pH adjuster is a basic compound and an acidic compound, which are different from the above-described compounds (the purine compound, the specific compound, the amine compound, and the like) which can be contained in the treatment liquid. However, it is permissible to adjust the pH of the treatment liquid by adjusting the adding amount of each of the above-described components.

The basic compound is a compound which exhibits alkalinity (a pH of more than 7.0) in an aqueous solution.

Examples of the basic compound include a basic inorganic compound.

Examples of the basic inorganic compound include alkali metal hydroxides such as sodium hydroxide and potassium hydroxide, and alkaline earth metal hydroxides.

The acidic compound is a compound which exhibits acidity (a pH of less than 7.0) in an aqueous solution.

Examples of the acidic compound include an acidic inorganic compound.

Examples of the acidic inorganic compound include hydrochloric acid, nitric acid, nitrous acid, and boric acid.

From the viewpoint that the effect of the present invention is more excellent, it is preferable that the treatment liquid does not contain ammonia (NH₃).

The pH adjuster may be used alone, or two or more types thereof may be used in combination.

A content of the pH adjuster can be selected depending on the type and amount of components other than the pH adjuster and the target pH of the treatment liquid. For example, the content of the pH adjuster is preferably 0.01% to 10% by mass, and more preferably 0.1% to 8% by mass with respect to the total mass of the treatment liquid.

### [Other Components]

The treatment liquid may contain, in addition to the above-described compounds, at least one component selected from the group consisting of a surfactant, an organic solvent, an organic acid, a polymer, a polyhydroxy compound having a molecular weight of 500 or more, and an oxidant.

Hereinafter, other components will be described.

### <Surfactant>

The surfactant is not particularly limited as long as it is a compound having a hydrophilic group and a hydrophobic group (lipophilic group) in one molecule; and examples thereof include a nonionic surfactant and an anionic surfactant.

In many cases, the surfactant has at least one hydrophobic group selected from the group consisting of an aliphatic hydrocarbon group, an aromatic hydrocarbon group, and a group obtained by combining these groups.

The number of carbon atoms in the surfactant is preferably 16 to 100.

Examples of the nonionic surfactant include an ester-type nonionic surfactant, an ether-type nonionic surfactant, an ester-ether-type nonionic surfactant, and an alkanolamine-type nonionic surfactant, and an ether-type nonionic surfactant is preferable.

As the nonionic surfactant, for example, compounds exemplified in paragraph [0126] of WO2022/044893A can also be used, the contents of which are incorporated herein by reference.

Examples of the anionic surfactant include a phosphoric acid ester-based surfactant having a phosphoric acid ester group, a phosphonic acid-based surfactant having a phosphonate group, and a carboxylic acid-based surfactant having a carboxy group.

As the anionic surfactant, for example, compounds exemplified in paragraphs [0118] and [0122] of WO2022/044893A can also be used, the contents of which are incorporated herein by reference.

The surfactant may be used alone, or two or more types thereof may be used in combination.

From the viewpoint of excellent performance of the treatment liquid, a content of the surfactant is preferably 0.001% to 8.0% by mass, more preferably 0.005% to 5.0% by mass, and still more preferably 0.01% to 3.0% by mass with respect to the total mass of the treatment liquid.

From the viewpoint of excellent performance of the treatment liquid, the content of the surfactant is preferably 0.01% to 50.0% by mass, more preferably 0.1% to 45.0% by mass, and still more preferably 1.0% to 20.0% by mass with respect to the total mass of components in the treatment liquid excluding a solvent.

### <Organic Solvent>

Examples of the organic solvent include known organic solvents, for example, an alcohol-based solvent, a glycol-based solvent, a glycol ether-based solvent, and a ketone-based solvent.

It is preferable that the organic solvent is mixed with water at an optional ratio.

Examples of the alcohol-based solvent include methanol, ethanol, propanol, isopropyl alcohol, 1-butanol, 2-butanol, isobutyl alcohol, and tert-butyl alcohol.

Examples of the glycol-based solvent include ethylene glycol, propylene glycol, diethylene glycol, dipropylene glycol, triethylene glycol, and tetraethylene glycol.

Examples of the glycol ether-based solvent include glycol monoether.

Examples of the glycol monoether include ethylene glycol monomethyl ether, ethylene glycol monoethyl ether, ethylene glycol mono-n-propyl ether, ethylene glycol monoisopropyl ether, ethylene glycol mono-n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

Examples of the ketone-based solvent include acetone, methyl ethyl ketone, methyl isobutyl ketone, and cyclohexanone.

The organic solvent may be used alone, or two or more types thereof may be used in combination.

A content of the organic solvent is preferably 0.01% to 15.0% by mass, more preferably 0.05% to 10.0% by mass, and still more preferably 0.1% to 5.0% by mass with respect to the total mass of the treatment liquid.

### <Organic Acid>

Examples of the organic acid include carboxylic acids such as an aliphatic carboxylic acid and an aromatic carboxylic acid, and a phosphonic acid.

The organic acid may be in a form of a salt. Examples of the above-described salt include an inorganic salt.

Examples of the aliphatic carboxylic acid include succinic acid, tartaric acid, maleic acid, oxalic acid, malonic acid, glutaric acid, adipic acid, pimelic acid, sebacic acid, formic acid, citric acid, malic acid, glycolic acid, gluconic acid, heptonic acid, and lactic acid.

Examples of the aromatic carboxylic acid include phenyl lactic acid, hydroxyphenyl lactic acid, phenyl succinic acid, phthalic acid, isophthalic acid, terephthalic acid, gallic acid, trimellitic acid, mellitic acid, and cinnamic acid.

As the phosphonic acid, compounds described in paragraphs [0026] to [0036] of WO2018/020878A and compounds ((co)polymers) described in paragraphs [0031] to [0046] of WO2018/030006A can be used, the contents of which are incorporated herein by reference.

The organic acid may be used alone, or two or more types thereof may be used in combination.

A content of the organic acid is preferably 0.0001% to 5.00% by mass, more preferably 0.0005% to 3.00% by mass, and still more preferably 0.001% to 1.00% by mass with respect to the total mass of the treatment liquid.

The content of the organic acid is preferably 0.1% to 50.0% by mass, more preferably 1.0% to 30.0% by mass, and still more preferably 3.0% to 10.0% by mass with respect to the total mass of components in the treatment liquid excluding a solvent.

### <Polymer>

Examples of the polymer include a water-soluble polymer.

The “water-soluble polymer” means a compound having two or more constitutional units linked in a linear or mesh form through a covalent bond, in which a mass of the polymer dissolved in 100 g of water at 20° C. is 0.1 g or more.

Examples of the water-soluble polymer include a polyacrylic acid, a polymethacrylic acid, a polymaleic acid, a polyvinylsulfonic acid, a polyallylsulfonic acid, a polystyrenesulfonic acid, and salts thereof; copolymers of monomers such as styrene, a-methylstyrene, and/or 4-methylstyrene and acid monomers such as a (meth)acrylic acid and/or a maleic acid, and salts thereof; polymers having constitutional units having an aromatic hydrocarbon group obtained by fusing benzenesulfonic acid and/or naphthalenesulfonic acid, and the like with formalin; polyglycerin; vinyl-based synthetic polymers such as polyvinyl alcohol, polyoxyethylene, polyvinylpyrrolidone, polyvinylpyridine, polyacrylamide, polyvinyl formamide, polyethyleneimine, polyvinyloxazoline, polyvinylimidazole, and polyallylamine; and modified products of natural polysaccharides such as hydroxyethyl cellulose, carboxymethyl cellulose, and processed starch.

As the polymer, water-soluble polymers described in paragraphs [0043] to [0047] of JP2016-171294A can also be used, the content of which is incorporated herein by reference.

A molecular weight (in a case of having a molecular weight distribution, a weight-average molecular weight) of the polymer is preferably 300 or more, more preferably more than 600, still more preferably 1,000 or more, particularly preferably more than 1,000, and most preferably 2,000 or more. The upper limit thereof is preferably 1,500,000 or less and more preferably 1,000,000 or less.

The polymer may be used alone, or two or more types thereof may be used in combination.

A content of the polymer is preferably 0.0001% to 5.00% by mass, more preferably 0.0005% to 3.00% by mass, and still more preferably 0.001% to 1.00% by mass with respect to the total mass of the treatment liquid.

The content of the polymer is preferably 0.1% to 50.0% by mass, more preferably 1.0% to 30.0% by mass, and still more preferably 3.0% to 10.0% by mass with respect to the total mass of components in the treatment liquid excluding a solvent.

### <Polyhydroxy Compound Having Molecular Weight of 500 or More>

As the polyhydroxy compound, compounds exemplified in paragraphs [0101] and [0102] of WO2022/014287A can be used, the contents of which are incorporated herein by reference.

### <Oxidant>

Examples of the oxidant include a peroxide, a persulfide (for example, a monopersulfide or a dipersulfide), a percarbonate, an acid thereof, and a salt thereof.

Examples of the oxidant include persorbic acid, a persorbate, a cerium compound, and a ferricyanide (potassium ferricyanide and the like).

A content of the oxidant is preferably 0.01% to 10.0% by mass, more preferably 0.05% to 5.0% by mass, and still more preferably 0.1% to 3.0% by mass with respect to the total mass of the treatment liquid.

The content of the oxidant is preferably 0.1% to 50.0% by mass, more preferably 1.0% to 30.0% by mass, and still more preferably 3.0% to 10.0% by mass with respect to the total mass of components in the treatment liquid excluding a solvent.

### <Halide>

The treatment liquid may contain a halide, but from the viewpoint that the effect of the present invention is more excellent, it is preferable that the treatment liquid does not substantially contain a halide (particularly, an inorganic halide).

The halide is a compound containing one or more halogen elements, and examples of the halogen element include one or two or more selected from the group consisting of fluorine, chlorine, bromine, and iodine. Examples of the halide include fluoride, chloride, bromide, and iodide.

Examples of the fluoride include NH₄F, HF, H₂SiF₆, H₂TiF₆, H₂ZrF₆, HPF₆, and HBF₄.

The fact that the halide is substantially not contained means that the content of the halide is 0.01% by mass or less with respect to the total mass of the treatment liquid, preferably 0.001% by mass or less and more preferably 0.0001% by mass or less. The lower limit thereof is, for example, 0% by mass.

A content of the various components which can be contained in the above-described treatment liquid can be measured, for example, according to a known method such as gas chromatography-mass spectrometry (GC-MS), liquid chromatography-mass spectrometry (LC-MS), and ion-exchange chromatography (IC).

### [0108][Physical Properties of Treatment Liquid]

Hereinafter, properties of the treatment liquid will be described in detail.

[0109]<pH>

The treatment liquid is basic and has a pH of more than 7.0.

From the viewpoint that the effect of the present invention is more excellent, the pH of the treatment liquid is preferably 9.0 to 14.0, more preferably 10.0 to 13.5, and still more preferably 10.5 to 13.0.

The pH of the treatment liquid can be measured by a method based on JIS Z 8802-1984 using a known pH meter. A measurement temperature of the pH is 25° C.

### <Metal Content>

A content (measured as ion concentration) of all metals (for example, metal elements of Fe, Co, Na, Cu, Mg, Mn, Li, Al, Cr, Ni, Zn, Sn, and Ag) contained as impurities in the treatment liquid is preferably 5 ppm by mass or less, and more preferably 1 ppm by mass or less. It is assumed that, in manufacturing of a cutting-edge semiconductor element, a treatment liquid having even higher purity is required, and thus the metal content thereof is more preferably a value lower than 1 mass ppm, that is, lower than a value of mass ppb order, particularly preferably 100 mass ppb or less, and most preferably less than 10 mass ppb. The lower limit thereof is preferably 0.

Examples of a method for reducing the metal content include performing a purifying treatment such as distillation and filtration using an ion exchange resin or a filter at a stage of raw materials used in the production of the treatment liquid or a stage after the production of the treatment liquid.

Other examples of the method for reducing the metal content include using a container with less elution of impurities, which will be described later, as a container that accommodates the raw material or the produced treatment liquid. In addition, other examples thereof include lining an interior wall of the pipe with a fluororesin to prevent the elution of metal components from a pipe or the like during the production of the treatment liquid.

### <Coarse Particles>

The treatment liquid may contain coarse particles, but it is preferable that a content thereof is preferably low.

The coarse particles mean particles having a diameter (particle size) of 0.03 m or more, in a case where a shape of the particles is regarded as a sphere.

The coarse particles contained in the treatment liquid correspond to, for example, particles such as rubbish, dust, organic solid, and inorganic solid, which are contained as impurities in raw materials, and particles such as rubbish, dust, organic solid, and inorganic solid, which are brought in as contaminants during the preparation of the treatment liquid, in which those particles are finally present as particles without being dissolved in the treatment liquid.

The content of the coarse particles in the treatment liquid, in terms of content of particles having a particle size of 0.1 m or more, is preferably 10,000 or less and more preferably 5,000 or less per 1 mL of the treatment liquid. A lower limit thereof is preferably 0 or more, and more preferably 0.01 or more per milliliter of the treatment liquid.

The content of the coarse particles present in the treatment liquid can be measured in a liquid phase by using a commercially available measuring device in a light scattering type liquid particle measuring method using a laser as a light source.

Examples of a method for removing the coarse particles include a purification treatment such as filtering, which will be described later.

### [0114][Production Method]

The treatment liquid can be produced by a known method. Hereinafter, a production method of the treatment liquid will be described in detail.

### [0115][Liquid Preparation Step]

The treatment liquid can be produced, for example, by mixing the above-described components.

Examples of the method for preparing the treatment liquid include a method in which the purine compound, the specific compound, and, as necessary, an optional component are sequentially charged into a container containing purified pure water, the mixture is stirred and mixed, and a pH adjuster is added as necessary to adjust the pH of the mixed solution, thereby preparing the treatment liquid. In addition, in a case where the water and the respective components are charged into the container, the water and the respective components may be charged at once, or may be charged in a divided manner a plurality of times.

As a stirring device and a stirring method used for preparing the treatment liquid, a known device may be used as a stirrer or a disperser. Examples of a stirrer include an industrial mixer, a portable stirrer, a mechanical stirrer, and a magnetic stirrer. Examples of the disperser include an industrial disperser, a homogenizer, an ultrasonic disperser, and a beads mill.

The mixing of the respective components in the step of preparing the treatment liquid, a refining treatment described later, and storage of the produced treatment liquid are preferably performed at 40° C. or lower, and more preferably performed at 30° C. or lower. The lower limit thereof is preferably 5° C. or higher and more preferably 10° C. or higher. By preparing, treating, and/or storing the treatment liquid in the above-described temperature range, stable performance can be maintained for a long period of time.

### <Purification Treatment>

It is preferable to subject any one or more of the raw materials for preparing the treatment liquid to a purification treatment in advance. Examples of the purification treatment include known methods such as distillation, ion exchange, and filtration (filtering).

Regarding a degree of purification, it is preferable to carry out the purification treatment until the purity of the raw material is 99% by mass or more, and it is more preferable to carry out the purification treatment until the purity of the raw material is 99.9% by mass or more. The upper limit thereof is preferably 99.9999% by mass or less.

Examples of a method of the purification treatment include a method of passing the raw material through an ion exchange resin, a reverse osmosis membrane (RO membrane), or the like, distillation of a raw material, and filtering described later.

The purification treatment may be carried out by combining a plurality of the above-described purification methods. For example, the raw materials are subjected to primary purification by passing through an RO membrane, and then subjected to secondary purification by passing through a purification device consisting of a cation-exchange resin, an anion-exchange resin, or a mixed-bed type ion exchange resin.

In addition, the purification treatment may be performed a plurality of times.

The filter which is used for filtering is not particularly limited as long as it has been used in application for filtering and the like in the related art. Examples thereof include filters formed of fluororesins such as polytetrafluoroethylene (PTFE) and tetrafluoroethylene perfluoroalkyl vinyl ether copolymer (PFA), polyamide-based resins such as nylon, polyolefin resins (including those with a high density and a ultra-high molecular weight) such as polyethylene and polypropylene (PP), or the like. Among these materials, a material selected from the group consisting of polyethylene, polypropylene (including a high-density polypropylene), a fluororesin (including PTFE and PFA), and a polyamide-based resin (including nylon) is preferable; and a filter of the fluororesin is more preferable. By carrying out filtering of the raw materials using a filter formed of these materials, high-polarity foreign matters which are likely to cause defects can be more effectively removed.

### <Container>

The treatment liquid (including an aspect of a diluted treatment liquid described later) can be added in any container to be stored and transported as long as problems such as corrosiveness do not arise.

In application for a semiconductor, the container is preferably a container which has a high degree of cleanliness inside the container and in which the elution of impurities from an interior wall of an accommodating portion of the container into the each liquid is suppressed. Examples of such a container include various containers commercially available as a container for a semiconductor treatment liquid, such as “CLEAN BOTTLE” series manufactured by AICELLO MILIM CHEMICAL Co., Ltd. and “PURE BOTTLE” manufactured by Kodama Plastics Co., Ltd., but the container is not limited thereto.

In addition, as the container, containers exemplified in paragraphs [0121] to [0124] of WO2022/004217A can also be used, the contents of which are incorporated herein by reference.

The inside of these containers is preferably cleaned before filling the treatment liquid. With regard to a liquid used for the cleaning, the amount of metal impurities in the liquid is preferably reduced. The treatment liquid may be bottled in a container such as a gallon bottle and a coated bottle after the production, and then may be transported and stored.

In order to prevent changes in the components of the treatment liquid during the storage, the inside of the container may be purged with an inert gas (such as nitrogen and argon) having a purity of 99.99995% by volume or more. In particular, a gas with a low moisture content is preferable. In addition, during the transportation and the storage, the temperature may be normal temperature or may be controlled in a range of −20° C. to 20° C. to prevent deterioration.

### <Clean Room>

It is preferable that handlings including production of the treatment liquid, opening and cleaning of the container, and filling of the treatment liquid, treatment analysis, and measurements are all performed in a clean room. It is preferable that the clean room meets the 14644-1 clean room standard. It is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

### [0126][Dilution Step]

The above-described treatment liquid may be used for treating an object as a diluted treatment liquid after undergoing a dilution step of diluting the treatment liquid using a diluent such as water.

The diluted treatment liquid is also an aspect of the treatment liquid according to the embodiment of the present invention as long as it satisfies the requirements of the present invention.

It is preferable to subject the diluted liquid which is used in the dilution step to a purification treatment in advance. In addition, it is more preferable that the diluted treatment liquid obtained in the dilution step is subjected to a purification treatment.

Examples of the purification treatment include the ion component reducing treatment using the ion exchange resin, the RO membrane, or the like, and the foreign matter removal using filtering, which are described as the purification treatment for the treatment liquid above, and it is preferable to carry out any one of these treatments.

A dilution rate of the treatment liquid in the dilution step may be appropriately adjusted depending on the type and content of each component and the object to be treated, but the ratio (dilution rate) of the diluted treatment liquid to the treatment liquid before the dilution is preferably 10 to 10,000 times, more preferably 20 to 3,000 times, and still more preferably 50 to 1,000 times in terms of mass ratio or volume ratio (volume ratio at 23° C.).

In addition, from the viewpoint of more excellent defect removability, the treatment liquid is preferably diluted with water.

A change in pH before and after the dilution (a difference between the pH of the treatment liquid before the dilution and the pH of the diluted treatment liquid) is preferably 2.0 or less, more preferably 1.8 or less, and still more preferably 1.5 or less.

It is preferable that the pH of the treatment liquid before the dilution and the pH of the diluted treatment liquid are each in the above-described suitable aspect.

A specific method for the dilution step of diluting the treatment liquid may be performed according to the step of preparing the treatment liquid described above. A stirring device and a stirring method used in the dilution step may also be performed using the known stirring device described in the step of preparing the treatment liquid above.

### [0131][Use Application]

The treatment liquid according to the embodiment of the present invention can be used for various materials used in the manufacturing of a semiconductor. Hereinafter, the object of the treatment liquid according to the embodiment of the present invention will be described in detail.

The above-described treatment liquid can be used, for example, for treating an insulating film, a resist, an antireflection film, an etching residue, an ashing residue, and the like, which are present on a substrate. The above-described treatment liquid is preferably used as a cleaning liquid, and more preferably used in a cleaning step of cleaning an object to be treated (particularly, a semiconductor substrate) which has been subjected to a CMP treatment.

As described above, in a case where the treatment liquid is used, the treatment liquid may be used as a diluted treatment liquid obtained by diluting the treatment liquid.

### [0133][Object]

Examples of the object to be treated with the treatment liquid include an object containing a metal; and a semiconductor substrate containing a metal is preferable.

In a case where the semiconductor substrate contains a metal, for example, the metal may be present on any of front and back surfaces, side surfaces, inside of a groove, and the like of the semiconductor substrate. In addition, in a case where the semiconductor substrate contains a metal, the metal includes not only a case in which the metal is directly present on the surface of the semiconductor substrate, but also a case in which the metal is present on the semiconductor substrate through another layer.

Examples of the metal include at least one metal M selected from the group consisting of copper (Cu), cobalt (Co), ruthenium (Ru), aluminum (Al), tungsten (W), titanium (Ti), tantalum (Ta), chromium (Cr), hafnium (Hf), osmium (Os), platinum (Pt), nickel (Ni), manganese (Mn), iron (Fe), zirconium (Zr), molybdenum (Mo), palladium (Pd), lanthanum (La), and iridium (Ir); and Cu or Co is preferable.

That is, the object is preferably an object containing at least one metal selected from the group consisting of Cu and Co.

The metal may be a substance containing metal (metal atom), and examples thereof include a simple substance of the metal M and an alloy containing the metal M.

The object to be treated with the treatment liquid may have, for example, a semiconductor substrate, a metal wire film, a barrier metal, and an insulating film.

Examples of the wafer constituting the semiconductor substrate include a wafer consisting of a silicon-based material, such as a silicon (Si) wafer, a silicon carbide (SiC) wafer, and a silicon-including resin-based wafer (glass epoxy wafer), a gallium phosphorus (GaP) wafer, a gallium arsenic (GaAs) wafer, and an indium phosphorus (InP) wafer.

Examples of the silicon wafer include an n-type silicon wafer in which a silicon wafer is doped with a pentavalent atom (for example, phosphorus (P), arsenic (As), antimony (Sb), or the like) and a p-type silicon wafer in which a silicon wafer is doped with a trivalent atom (for example, boron (B), gallium (Ga), or the like). Examples of the silicon of the silicon wafer include amorphous silicon, single crystal silicon, polycrystalline silicon, and polysilicon.

Among these, a wafer consisting of a silicon-based material, such as a silicon wafer, a silicon carbide wafer, and a resin-based wafer (a glass epoxy wafer) including silicon, is preferable.

Examples of the insulating film include a silicon oxide film (for example, a silicon dioxide (SiO₂) film, a tetraethyl orthosilicate (Si(OC₂H₅)₄) film (a TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film and a silicon carbide (SiC) film); and a low-dielectric-constant (Low-k) film is preferable.

As the metal wire film, a copper-containing film, a cobalt-containing film, or a ruthenium-containing film is preferable.

Examples of the copper-containing film include a wire film consisting of only metal copper (copper wire film), and a wire film made of an alloy consisting of metal copper and another metal (a copper alloy wire film).

Specific examples of the copper alloy wire film include a wire film made of an alloy consisting of one or more metals selected from Al, Ti, Cr, Mn, Ta, and W, and copper. More specific examples of the copper alloy wire film include a copper-aluminum alloy wire film (CuAl alloy wire film), a copper-titanium alloy wire film (CuTi alloy wire film), a copper-chromium alloy wire film (CuCr alloy wire film), a copper-manganese alloy wire film (CuMn alloy wire film), a copper-tantalum alloy wire film (CuTa alloy wire film), and a copper-tungsten alloy wire film (CuW alloy wire film).

Examples of the cobalt-containing film include a metal film consisting of only metal cobalt (cobalt metal film) and a metal film made of an alloy consisting of metal cobalt and another metal (cobalt alloy metal film).

Examples of the cobalt alloy metal film include a metal film made of an alloy consisting of one or more metals selected from Ti, Cr, Fe, Ni, Mo, Pd, Ta, and W, and cobalt. More specific examples of the cobalt alloy metal film include a cobalt-titanium alloy metal film (a CoTi alloy metal film), a cobalt-chromium alloy metal film (a CoCr alloy metal film), a cobalt-iron alloy metal film (a CoFe alloy metal film), a cobalt-nickel alloy metal film (a CoNi alloy metal film), a cobalt-molybdenum alloy metal film (a CoMo alloy metal film), a cobalt-palladium alloy metal film (a CoPd alloy metal film), a cobalt-tantalum alloy metal film (a CoTa alloy metal film), and a cobalt-tungsten alloy metal film (a CoW alloy metal film).

The treatment liquid is useful for a substrate having the cobalt-containing film. Among the cobalt-containing films, the cobalt metal film is usually used as a wire film, and the cobalt alloy metal film is usually used as a barrier metal.

Examples of the ruthenium-containing film include a metal film consisting of only metal ruthenium (ruthenium metal film) and a metal film made of an alloy consisting of metal ruthenium and another metal (ruthenium alloy metal film). The ruthenium-containing film is usually used as a barrier metal.

A method of forming the insulating film, the copper-containing film, the cobalt-containing film, and the ruthenium-containing film on the wafer constituting the semiconductor substrate is not particularly limited as long as it is a method generally carried out in this field.

Examples of the method of forming the insulating film include a method in which the wafer constituting the semiconductor substrate is subjected to a heat treatment in the presence of oxygen gas to form a silicon oxide film, and then a gas of silane and ammonia is introduced thereto to form a silicon nitride film by a chemical vapor deposition (CVD) method.

Examples of the method of forming the copper-containing film, the cobalt-containing film, and the ruthenium-containing film include a method of forming a circuit on a wafer having the above-described insulating film by a known method such as a resist, and then forming the copper-containing film, the cobalt-containing film, and the ruthenium-containing film by a method such as plating and a CVD method.

<Object which has been Subjected to CMP Treatment>

As the object in a case of using the treatment liquid for cleaning, an object (particularly, a semiconductor substrate) which has been subjected to the CMP treatment is preferable; and an object containing at least one metal selected from the group consisting of Cu and Co, which has been subjected to the CMP treatment, is more preferable.

The CMP treatment is a treatment in which a surface of the semiconductor substrate having the metal wire film, the barrier metal, and the insulating film is flattened by a combined action of a chemical action and a mechanical polishing using a polishing slurry including polishing fine particles (abrasive grains).

A surface of the object which has been subjected to the CMP treatment may have impurities remaining thereon, such as abrasive grains (for example, silica and alumina) used in the CMP treatment, a polished metal wire film, and metal impurities (metal residue) derived from the barrier metal. In addition, organic impurities derived from a CMP treatment liquid used in the CMP treatment may remain. For example, since these impurities may cause a short-circuit between wiring lines and deteriorate electrical characteristics of the semiconductor substrate, the semiconductor substrate which has been subjected to the CMP treatment is subjected to a cleaning treatment for removing these impurities from the surface.

Specific examples of the object which has been subjected to the CMP treatment include substrates which have been subjected to the CMP treatment, described in Journal of the Japan Society for Precision Engineering, Vol. 84, No. 3, 2018, but the present invention is not limited thereto.

<Object which has been Subjected to Buffing>

An object (particularly, a semiconductor substrate) in a case of using the treatment liquid for cleaning may be subjected to a buffing treatment after being subjected to the CMP treatment.

The buffing treatment is a treatment of reducing impurities on the surface of the semiconductor substrate using a polishing pad. Specifically, the surface of the semiconductor substrate which has been subjected to the CMP treatment is brought into contact with the polishing pad, and the semiconductor substrate and the polishing pad are relatively slid while supplying a composition for buffing to a contact portion. As a result, impurities on the surface of the semiconductor substrate are removed by a frictional force of the polishing pad and a chemical action of a composition for buffing.

As the composition for buffing, a known composition for buffing can be appropriately used depending on the type of the semiconductor substrate, and the type and amount of the impurities to be removed. Examples of components contained in the composition for buffing include a water-soluble polymer such as polyvinyl alcohol, water as a dispersion medium, and an acid such as nitric acid.

In addition, as an embodiment of the buffing treatment, it is also preferable to use a treatment liquid as the composition for buffing.

A polishing device, polishing conditions, and the like, which are used in the buffing treatment, can be appropriately selected from known devices and conditions according to the type of the semiconductor substrate, the object to be removed, and the like. Examples of the buffing treatment include treatments described in paragraphs [0085] to [0088] of WO2017/169539A, the contents of which are incorporated herein by reference.

### [0147][Method of Using Treatment Liquid]

The treatment liquid can be used by a known method. Hereinafter, a method of using the treatment liquid will be described in detail.

### [0148][Treatment Step]

Examples of the method of using the treatment liquid include a treatment method for an object, which includes a step of bringing the object to be treated into contact with the treatment liquid. Hereinafter, the step of bringing the object into contact with the treatment liquid is also referred to as “contact step”.

The method of bringing the object into contact with the treatment liquid is not particularly limited; and examples thereof include a method of immersing the object in the treatment liquid contained in a tank, a method of spraying the treatment liquid onto the object, a method of flowing the treatment liquid onto the object, and a combination thereof. The above-described method may be appropriately selected depending on the purpose.

In addition, the above-described method may appropriately adopt a method usually performed in the field. For example, scrub cleaning in which a cleaning member such as a brush is physically brought into contact with a surface of the object while supplying the treatment liquid to remove residues and the like, spinning (dropping) cleaning in which the treatment liquid is dropped while rotating the object, or the like may be used. From the viewpoint that impurities remaining on a surface of the object can be further reduced, it is preferable that the object immersed in the treatment liquid is subjected to an ultrasonic treatment.

The contact between the object and the treatment liquid in the contact step may be carried out only once or twice or more. In a case of carrying out the contact twice or more, the same method may be repeated or different methods may be combined.

A method for the contact step may be a single-wafer method or a batch method.

The single-wafer method is generally a method of treating the objects one by one, and the batch method is generally a method of treating a plurality of the objects at the same time.

A temperature of the treatment liquid is not particularly limited as long as it is a temperature usually used in this field. Generally, the cleaning is carried out at room temperature (approximately 25° C.), but any temperature can be selected in order to improve the defect removability and suppress the damage resistance to a member. For example, the temperature of the treatment liquid is preferably 10° C. to 60° C., and more preferably 15° C. to 50° C.

A contact time between the object and the treatment liquid can be appropriately changed depending on the type and content of each component contained in the treatment liquid, and the use target and purpose of the treatment liquid. The contact time is practically 10 to 120 seconds, preferably 20 to 90 seconds and more preferably 30 to 60 seconds.

A supply amount (supply rate) of the treatment liquid is preferably 50 to 5,000 mL/min, and more preferably 500 to 2,000 mL/min.

In the contact step, a mechanical stirring method may be used in order to further improve the cleaning ability of the treatment liquid.

Examples of the mechanical stirring method include a method of circulating the treatment liquid on the object, a method of flowing or spraying the treatment liquid on the object, and a method of stirring the treatment liquid with ultrasonic wave or megasonic wave.

### [Rinsing Step]

In addition, after the contact step, a step of bringing the object to be treated into contact with water (hereinafter, also referred to as “rinsing step”) may be performed. By performing the rinsing step, the object to be treated obtained in the contact step can be washed with water, and the above-described defects derived from the purine compound can be efficiently removed.

The rinsing step is preferably performed continuously after the contact step. The rinsing step may be performed using the above-described mechanical stirring method.

As the method in which the water is brought into contact with the object to be treated, the method in which the treatment liquid is brought into contact with the object can be similarly applied.

A contact time between the object to be treated and the water can be appropriately changed depending on the type and content of each component contained in the treatment liquid, and the use target and purpose of the treatment liquid. The contact time is practically 10 to 120 seconds, preferably 20 to 90 seconds and more preferably 30 to 60 seconds.

A drying step of drying the object to be treated may be performed after the above-described rinsing step.

Examples of the drying method include a spin drying method, a method of flowing a dry gas onto the object to be treated, a method of heating a substrate by a heating unit such as a hot plate and an infrared lamp, and a method of combining any of these methods.

### [Manufacturing Method of Electronic Device]

The above-described treatment method for an object can be suitably applied to a manufacturing process of an electronic device.

The above-described treatment method may be performed in combination before or after other steps performed on a substrate. The above-described treatment method may be incorporated into other steps while performing the treatment method, or the above-described treatment method may be incorporated into the other steps.

Examples of the other steps include a step of forming each structure such as a metal wire, a gate structure, a source structure, a drain structure, an insulating film, a ferromagnetic layer, and a non-magnetic layer (for example, layer formation, etching, chemical mechanical polishing, modification, or the like), a resist forming step, an exposure step and a removal step, a heat treatment step, a cleaning step, and an examination step.

The above-described treatment method may be performed at any stage among the back-end process (BEOL: back end of the line), the middle process (MOL: middle of the line), and the front-end process (FEOL: front end of the line); and it is preferable that the treatment method be performed in a front-end process or a middle process.

### EXAMPLES

Hereinafter, the present invention will be described in more detail with reference to Examples.

The materials, the amounts and proportions of the materials used, the details of treatments, the procedure of treatments, and the like shown in the following Examples can be appropriately modified as long as the gist of the present invention is maintained. Therefore, the scope of the present invention should not be construed as being limited to Examples shown below.

In the following Examples, a pH of the treatment liquid was measured at 25° C. using a pH meter (manufactured by HORIBA, Ltd., model “F-74”) in accordance with JIS Z 8802-1984.

In addition, in production of treatment liquids of Examples and Comparative Examples, all of handling of a container, and production, filling, storage, and analytical measurement of the treatment liquids were performed in a clean room satisfying a level of ISO Class 2 or lower.

### [Raw Materials of Treatment Liquid]

The following compounds were used to produce a treatment liquid. As various components used in Examples, those all classified into a semiconductor grade or a high-purity grade equivalent thereto were used.

[Purine compound]
Adenine (corresponding to the compound represented by Formula (A1))
Xanthine (corresponding to the compound represented by Formula (A4))
Hypoxanthine (corresponding to the compound represented by Formula (A5))
Guanine (corresponding to the compound represented by Formula (A5))
Adenosine (corresponding to the compound represented by Formula (A1))
Caffeine (corresponding to the compound represented by Formula (A4))
Benzyladenine (corresponding to the compound represented by Formula (A1))

### [Specific Compound]

Sulfuric acid (pKa=−3.2)
Paratoluenesulfonic acid (pKa=−0.4)
Methanesulfonic acid (pKa=−1.8)
Ethanesulfonic acid (pKa=−1.8)
1,2-Ethanedisulfonic acid (pKa=−0.7)
Benzenesulfonic acid (pKa=−0.6)

The above-described pKa is a value calculated using “ACD/Pka DB Ver 8.0” (manufactured by ACD/Labs, Advanced Chemistry Development, Inc.).

In a case where the specific compound exhibited a plurality of pKa's, the smallest pKa value is shown above.

[Amine compound]
DMAMP: 2-(dimethylamino)-2-methyl-1-propanol
ETMAH: ethyltrimethylammonium hydroxide
THEMAH: tris(2-hydroxyethyl)methylammonium hydroxide
Choline: 2-hydroxyethyltrimethylammonium hydroxide
TEAH: tetraethylammonium hydroxide
PMDETA: N,N,N′,N″,N″-pentamethyldiethylenetriamine
AMP: 2-amino-2-methyl-1-propanol
MAMP: N-methyl-2-amino-2-methyl-propanol
   [Other compounds]
Acetic acid
Phosphoric acid
DBS: dodecylbenzene sulfonic acid
Succinic acid
Tartaric acid
Maleic acid
Polyacrylic acid (Mw=5,000)
IPA: Isopropyl alcohol
EGBE: ethylene glycol mono-n-butyl ether

In the treatment liquid, the remaining component (remainder) other than components specified as the components of the treatment liquid in the tables was ultrapure water and the pH adjuster.

### [Production of Treatment Liquid]

Next, a production method of a treatment liquid will be described with reference to Example 1.

Adenine, sulfuric acid, and DMAMP were each added to ultrapure water so that the finally obtained treatment liquid had the formulation shown in the tables below, and the obtained mixed solution was sufficiently stirred. Furthermore, a pH adjuster (potassium hydroxide) was added as necessary so that the treatment liquid had a pH shown in the tables below, and the mixture was sufficiently stirred to obtain a treatment liquid of Example 1.

According to the production method of Example 1, a treatment liquid of each of Examples or each of Comparative Examples, having the formulation shown in the tables below, was produced.

[Evaluation 1 of Treatment Liquid: Semiconductor Substrate after CMP]

The obtained treatment liquid was evaluated for anticorrosion properties and defect removability. Hereinafter, the evaluation method will be described.

### [Evaluation of Anticorrosion Properties]

Using the treatment liquid produced by the above-described method, anticorrosion properties against Cu and Co were evaluated.

A Cu or Co wafer having a size of 2×2 cm was prepared.

The above-described wafer was placed in a container filled with the treatment liquid of each of Examples or each of Comparative Examples, and subjected to an immersion treatment at room temperature (25° C.) for 30 minutes. Thereafter, a film thickness of the wafer obtained using VR250 (manufactured by Kokusai Electric Semiconductor Service Inc.) was measured, and an etching rate (A/min) was determined from the difference in film thickness before and after the above-described immersion treatment.

The anticorrosion properties of the treatment liquid were evaluated according to the following evaluation standard. As the etching rate was lower, the anticorrosion properties were better.
A: less than 0.4 A/min
B: 0.4 A/min or more and less than 0.6 A/min
C: 0.6 A/min or more and less than 0.8 A/min
D: 0.8 A/min or more

### [Evaluation of Defect Removability]

The defect removability was evaluated in a case where a semiconductor substrate subjected to a CMP treatment was cleaned using the treatment liquid produced by the above-described method.

Using FREX300S-II (polishing device, manufactured by EBARA CORPORATION), a wafer (diameter: 12 inches) having a Cu film or a Co film on a surface was polished under conditions in which a polishing liquid 1 was used as a polishing liquid, an in-plane average value of a polishing pressure was 105 hPa, a supply rate of the polishing liquid was 200 mL/min, and a polishing time was 30 seconds. Next, the wafer subjected to the above-described polishing treatment was polished under conditions in which a polishing liquid 2 was used as a polishing liquid, an in-plane average value of a polishing pressure was 70 hPa, a supply rate of the polishing liquid was 200 mL/min, and a polishing time was 60 seconds.

The obtained wafer subjected to the CMP treatment was subjected to scrub cleaning for 1 minute using a sample of the treatment liquid adjusted to room temperature (23° C.), washed with DI water for 30 seconds, and then subjected to a drying treatment.

Formulations of the polishing liquid 1 and the polishing liquid 2 described above were as follows.

Polishing liquid 1 (pH: 7.0)
Colloidal silica (PL3, manufactured by FUSO CHEMICAL CO., LTD.) 0.1% by mass

| Polishing liquid 1 (pH: 7.0) | | |
|---|---|---|
| Colloidal silica (PL3, manufactured | 0.1% | by mass |
| by FUSO CHEMICAL CO., LTD.) | | |
| Glycine | 1.0% | by mass |
| 3-Amino-1,2,4-triazole | 0.2% | by mass |
| Benzotriazole (BTA) | 30 | ppm by mass |
| Hydrogen peroxide | 1.0% | by mass |
| pH adjuster (ammonia and nitric acid) | | |
| Water | remainder | |
| Polishing liquid 2 (pH: 10.5) | | |
| Colloidal silica (PL3, manufactured by FUSO | 6.0% | by mass |
| CHEMICAL CO., LTD.) | | |
| Citric acid | 1.0% | by mass |
| Alkylalkoxylate surfactant | 100 | ppm by mass |
| BTA | 0.2% | by mass |
| Hydrogen peroxide | 1.0% | by mass |
| pH adjuster (potassium hydroxide and nitric acid) | | |

| | |
|---|---|
| Water | remainder |

Next, a defect detection device (ComPlus-II, manufactured by AMAT) was used to measure the number of detections of signal intensities corresponding to defects having a length of more than 0.1 m on the obtained polished surface of the wafer. As a result, the number of defects based on residues on the polished surface of the wafer was obtained.

The defect removability of the treatment liquid was evaluated according to the following evaluation standard. As the number of defects detected on the polished surface of the wafer was smaller, the defect removability was better.
A: number of defects per wafer was less than 200.
B: number of defects per wafer was 200 or more and less than 300.
C: number of defects per wafer was 300 or more and less than 500.
D: number of defects per wafer was 500 or more.

### [Result]

In the tables, the column of “Content (% by mass” indicates the content (% by mass) of each component with respect to the total mass of the treatment liquid.

In the tables, the column of “Concentration of solid contents (% by mass)” indicates the content (% by mass) of each component with respect to the total mass of components in the treatment liquid excluding a solvent.

In the tables, the numerical value in the column of “(B)/(A)” indicates the mass ratio of the content (B) of the specific compound to the content (A) of the purine compound (content (B) of specific compound/content (A) of purine compound).

In the tables, the numerical value in the column of “(B)/(C)” indicates the mass ratio of the content (B) of the specific compound to the content (C) of the amine compound (content (B) of specific compound/content (C) of amine compound).

In the tables, the numerical value in the column of pH indicates the pH of the treatment liquid at 25° C., which was measured by the above-described pH meter.

TABLE 1

| | Semiconductor treatment liquid | | | | | | | | |
|---|---|---|---|---|---|---|---|---|---|
| | Purine compound (A) | | | Specific compound (B) | | | | Amine | |
| | | | Concentration | | | Concentration | | compound (C) | |
| | | Content | of solid | | Content | of solid | | | Content |
| | | (% by | contents | | (% by | contents | | | (% by |
| | Type | mass) | (% by mass) | Type | mass) | (% by mass) | (B)/(A) | Type | mass) |
| Example 1 | Adenine | 0.001 | 1.8 | Sulfuric | 0.0033 | 6.1 | 3.3 | DMAMP | 0.05 |
| | | | | acid | | | | | |
| Example 2 | Xanthine | 0.001 | 1.8 | Sulfuric | 0.0033 | 6.1 | 3.3 | DMAMP | 0.05 |
| | | | | acid | | | | | |
| Example 3 | Hypoxanthine | 0.001 | 1.8 | Sulfuric | 0.0033 | 6.1 | 3.3 | DMAMP | 0.05 |
| | | | | acid | | | | | |
| Example 4 | Guanine | 0.001 | 1.8 | Sulfuric | 0.0033 | 6.1 | 3.3 | DMAMP | 0.05 |
| | | | | acid | | | | | |
| Example 5 | Adenosine | 0.001 | 1.8 | Sulfuric | 0.0033 | 6.1 | 3.3 | DMAMP | 0.05 |
| | | | | acid | | | | | |
| Example 6 | Caffeine | 0.001 | 1.8 | Sulfuric | 0.0033 | 6.1 | 3.3 | DMAMP | 0.05 |
| | | | | acid | | | | | |
| Example 7 | Benzyladenine | 0.001 | 1.8 | Sulfuric | 0.0033 | 6.1 | 3.3 | DMAMP | 0.05 |
| | | | | acid | | | | | |
| Example 8 | Adenine | 0.001 | 1.8 | Paratoluene- | 0.0033 | 6.1 | 3.3 | DMAMP | 0.05 |
| | | | | sulfonic | | | | | |
| | | | | acid | | | | | |
| Example 9 | Adenine | 0.001 | 1.8 | Methane- | 0.0033 | 6.1 | 3.3 | DMAMP | 0.05 |
| | | | | sulfonic | | | | | |
| | | | | acid | | | | | |
| Example 10 | Adenine | 0.001 | 1.8 | Ethane- | 0.0033 | 6.1 | 3.3 | DMAMP | 0.05 |
| | | | | sulfonic | | | | | |
| | | | | acid | | | | | |
| Example 11 | Adenine | 0.001 | 1.8 | 1,2-Ethane- | 0.0033 | 6.1 | 3.3 | DMAMP | 0.05 |
| | | | | disulfonic | | | | | |
| | | | | acid | | | | | |
| Example 12 | Adenine | 0.001 | 1.8 | Benzene- | 0.0033 | 6.1 | 3.3 | DMAMP | 0.05 |
| | | | | sulfonic | | | | | |
| | | | | acid | | | | | |
| Example 13 | Adenine | 0.001 | 1.9 | Sulfuric | 0.0005 | 1.0 | 0.5 | DMAMP | 0.05 |
| | | | | acid | | | | | |
| Example 14 | Adenine | 0.001 | 1.9 | Sulfuric | 0.0010 | 1.9 | 1.0 | DMAMP | 0.05 |
| | | | | acid | | | | | |
| Example 15 | Adenine | 0.001 | 1.8 | Sulfuric | 0.0050 | 8.9 | 5.0 | DMAMP | 0.05 |
| | | | | acid | | | | | |
| Example 16 | Adenine | 0.001 | 1.4 | Sulfuric | 0.018 | 26.1 | 18.0 | DMAMP | 0.05 |
| | | | | acid | | | | | |
| Example 17 | Adenine | 0.001 | 1.3 | Sulfuric | 0.025 | 32.9 | 25.0 | DMAMP | 0.05 |
| | | | | acid | | | | | |
| Example 18 | Adenine | 0.001 | 1.4 | Sulfuric | 0.018 | 26.1 | 18.0 | DMAMP | 0.05 |
| | | | | acid | | | | | |
| Example 19 | Adenine | 0.001 | 1.3 | Sulfuric | 0.025 | 32.9 | 25.0 | DMAMP | 0.05 |
| | | | | acid | | | | | |
| Example 20 | Adenine | 0.0001 | 0.2 | Sulfuric | 0.0033 | 6.2 | 33.0 | DMAMP | 0.05 |
| | | | | acid | | | | | |
| Example 21 | Adenine | 0.005 | 8.6 | Sulfuric | 0.0033 | 5.7 | 0.7 | DMAMP | 0.05 |
| | | | | acid | | | | | |
| Example 22 | Adenine | 0.010 | 15.8 | Sulfuric | 0.0033 | 5.2 | 0.3 | DMAMP | 0.05 |
| | | | | acid | | | | | |

| | Semiconductor treatment liquid | | | | | | | |
|---|---|---|---|---|---|---|---|---|
| | | Additive | | | Object | | | |
| | | | Content | | Anticorrosion | | Defect | |
| | | | (% by | | properties | | removability | |
| | (B)/(C) | Type | mass) | pH | Cu | Co | Cu | Co |
| Example 1 | 0.066 | — | — | 10.9 | A | A | A | A |
| Example 2 | 0.066 | — | — | 10.9 | A | A | A | A |
| Example 3 | 0.066 | — | — | 10.9 | A | A | B | B |
| Example 4 | 0.066 | — | — | 10.9 | A | A | B | B |
| Example 5 | 0.066 | — | — | 10.9 | A | A | B | B |
| Example 6 | 0.066 | — | — | 10.9 | B | B | B | B |
| Example 7 | 0.066 | — | — | 10.9 | A | A | B | B |
| Example 8 | 0.066 | — | — | 11.0 | A | A | A | A |
| Example 9 | 0.066 | — | — | 10.9 | A | A | A | A |
| Example 10 | 0.066 | — | — | 11.0 | A | A | A | A |
| Example 11 | 0.066 | — | — | 11.0 | A | A | A | A |
| Example 12 | 0.066 | — | — | 11.0 | A | A | A | A |
| Example 13 | 0.010 | — | — | 11.1 | A | A | B | B |
| Example 14 | 0.020 | — | — | 11.0 | A | A | A | A |
| Example 15 | 0.100 | — | — | 10.9 | A | A | A | A |
| Example 16 | 0.360 | — | — | 10.0 | B | B | B | B |
| Example 17 | 0.500 | — | — | 9.0 | C | C | C | C |
| Example 18 | 0.360 | — | — | 11.0 | A | B | B | B |
| Example 19 | 0.500 | — | — | 11.0 | B | B | B | B |
| Example 20 | 0.066 | — | — | 10.9 | B | B | A | A |
| Example 21 | 0.066 | — | — | 10.9 | A | A | B | B |
| Example 22 | 0.066 | — | — | 10.9 | A | A | C | C |

TABLE 2

| | Semiconductor treatment liquid | | | | | | | | |
|---|---|---|---|---|---|---|---|---|---|
| | | | | | | | | Amine | |
| | Purine compound (A) | | | Specific compound (B) | | | | compound (C) | |
| | | Content | Concentration of | | Content | Concentration of | | | Content |
| | | (% by | solid contents | | (% by | solid contents | | | (% by |
| | Type | mass) | (% by mass) | Type | mass) | (% by mass) | (B)/(A) | Type | mass) |
| Example 23 | Adenine | 0.001 | 1.8 | Sulfuric | 0.0033 | 6.1 | 3.3 | ETMAH | 0.05 |
| | | | | acid | | | | | |
| Example 24 | Adenine | 0.001 | 1.8 | Sulfuric | 0.0033 | 6.1 | 3.3 | THEMAH | 0.05 |
| | | | | acid | | | | | |
| Example 25 | Adenine | 0.001 | 1.8 | Sulfuric | 0.0033 | 6.1 | 3.3 | Choline | 0.05 |
| | | | | acid | | | | | |
| Example 26 | Adenine | 0.001 | 1.8 | Sulfuric | 0.0033 | 6.1 | 3.3 | TEAH | 0.05 |
| | | | | acid | | | | | |
| Example 27 | Adenine | 0.001 | 0.9 | Sulfuric | 0.0033 | 2.9 | 3.3 | ETMAH | 0.11 |
| | | | | acid | | | | | |
| Example 28 | Adenine | 0.001 | 1.6 | Sulfuric | 0.0033 | 5.1 | 3.3 | DMAMP | 0.05 |
| | | | | acid | | | | PMDETA | 0.01 |
| Example 29 | Adenine | 0.001 | 1.6 | Sulfuric | 0.0033 | 5.1 | 3.3 | DMAMP | 0.05 |
| | | | | acid | | | | AMP | 0.01 |
| Example 30 | Adenine | 0.001 | 1.6 | Sulfuric | 0.0033 | 5.1 | 3.3 | DMAMP | 0.05 |
| | | | | acid | | | | MAMP | 0.01 |
| Example 31 | Hypoxanthine | 0.001 | 1.6 | Sulfuric | 0.0033 | 5.1 | 3.3 | DMAMP | 0.05 |
| | | | | acid | | | | PMDETA | 0.01 |
| Example 32 | Guanine | 0.001 | 1.6 | Sulfuric | 0.0033 | 5.1 | 3.3 | DMAMP | 0.05 |
| | | | | acid | | | | PMDETA | 0.01 |
| Example 33 | Adenine | 0.0004 | 0.9 | Sulfuric | 0.0033 | 7.6 | 8.3 | ETMAH | 0.02 |
| | | | | acid | | | | PMDETA | 0.02 |
| Example 34 | Adenine | 0.0004 | 0.9 | Sulfuric | 0.0033 | 7.6 | 8.3 | DMAMP | 0.02 |
| | | | | acid | | | | PMDETA | 0.02 |
| Example 35 | Adenine | 0.001 | 1.6 | Sulfuric | 0.0033 | 5.1 | 3.3 | ETMAH | 0.05 |
| | | | | acid | | | | PMDETA | 0.01 |
| Example 36 | Guanine | 0.0004 | 0.9 | Sulfuric | 0.0033 | 7.6 | 8.3 | ETMAH | 0.02 |
| | | | | acid | | | | PMDETA | 0.02 |
| Example 37 | Hypoxanthine | 0.0004 | 0.9 | Sulfuric | 0.0033 | 7.6 | 8.3 | ETMAH | 0.02 |
| | | | | acid | | | | PMDETA | 0.02 |
| Example 38 | Adenine | 0.001 | 1.6 | Sulfuric | 0.0033 | 5.1 | 3.3 | DMAMP | 0.05 |
| | | | | acid | | | | PMDETA | 0.008 |
| | | | | | | | | AMP | 0.002 |

| | Semiconductor treatment liquid | | | | | | | |
|---|---|---|---|---|---|---|---|---|
| | | Additive | | | Object | | | |
| | | | Content | | Anticorrosion | | Defect | |
| | | | (% by | | properties | | removability | |
| | (B)/(C) | Type | mass) | pH | Cu | Co | Cu | Co |
| Example 23 | 0.066 | — | — | 11.7 | A | A | A | A |
| Example 24 | 0.066 | — | — | 11.3 | A | A | A | A |
| Example 25 | 0.066 | — | — | 11.5 | A | A | A | A |
| Example 26 | 0.066 | — | — | 11.7 | A | A | A | A |
| Example 27 | 0.030 | — | — | 12.0 | A | A | A | A |
| Example 28 | 0.055 | — | — | 11.1 | A | A | A | A |
| Example 29 | 0.055 | — | — | 11.1 | A | A | A | A |
| Example 30 | 0.055 | — | — | 11.1 | A | A | A | A |
| Example 31 | 0.055 | — | — | 11.1 | A | A | A | A |
| Example 32 | 0.055 | — | — | 11.1 | A | A | A | A |
| Example 33 | 0.083 | — | — | 11.3 | A | A | A | A |
| Example 34 | 0.083 | — | — | 10.9 | A | A | A | A |
| Example 35 | 0.055 | — | — | 11.8 | A | A | A | A |
| Example 36 | 0.083 | — | — | 11.3 | A | A | A | A |
| Example 37 | 0.083 | — | — | 11.3 | A | A | A | A |
| Example 38 | 0.055 | — | — | 11.1 | A | A | A | A |

TABLE 3

| | Semiconductor treatment liquid | | | | | | | | |
|---|---|---|---|---|---|---|---|---|---|
| | Purine compound (A) | | | Specific compound (B) | | | | Amine | |
| | | | Concentration | | | Concentration | | compound (C) | |
| | | Content | of solid | | Content | of solid | | | Content |
| | | (% by | contents | | (% by | contents | | | (% by |
| | Type | mass) | (% by mass) | Type | mass) | (% by mass) | (B)/(A) | Type | mass) |
| Example 39 | Adenine | 0.0005 | 1.8 | Sulfuric | 0.0033 | 6.1 | 3.3 | DMAMP | 0.05 |
| | Adenosine | 0.0005 | | acid | | | | | |
| Example 40 | Adenine | 0.001 | 1.8 | Sulfuric | 0.0023 | 6.1 | 3.3 | DMAMP | 0.05 |
| | | | | acid | | | | | |
| | | | | Paratoluene- | 0.0010 | | | | |
| | | | | sulfonic | | | | | |
| | | | | acid | | | | | |
| Example 41 | Guanine | 0.001 | 1.8 | Sulfuric | 0.0033 | 6.1 | 3.3 | AMP | 0.05 |
| | | | | acid | | | | | |
| Example 42 | Guanine | 0.001 | 1.8 | Sulfuric | 0.0033 | 6.1 | 3.3 | MAMP | 0.05 |
| | | | | acid | | | | | |
| Example 43 | Guanine | 0.001 | 1.8 | Sulfuric | 0.0033 | 6.1 | 3.3 | PMDETA | 0.05 |
| | | | | acid | | | | | |
| Example 44 | Adenine | 0.001 | 1.8 | Sulfuric | 0.0033 | 6.0 | 3.3 | DMAMP | 0.05 |
| | | | | acid | | | | | |
| Example 45 | Adenine | 0.001 | 1.8 | Sulfuric | 0.0033 | 6.0 | 3.3 | DMAMP | 0.05 |
| | | | | acid | | | | | |
| Example 46 | Adenine | 0.001 | 1.8 | Sulfuric | 0.0033 | 6.0 | 3.3 | DMAMP | 0.05 |
| | | | | acid | | | | | |
| Example 47 | Adenine | 0.001 | 1.8 | Sulfuric | 0.0033 | 6.0 | 3.3 | DMAMP | 0.05 |
| | | | | acid | | | | | |
| Example 48 | Adenine | 0.001 | 1.8 | Sulfuric | 0.0033 | 6.1 | 3.3 | DMAMP | 0.05 |
| | | | | acid | | | | | |
| Example 49 | Adenine | 0.001 | 1.8 | Sulfuric | 0.0033 | 6.1 | 3.3 | DMAMP | 0.05 |
| | | | | acid | | | | | |
| Example 50 | Adenine | 0.100 | 1.8 | Sulfuric | 0.3300 | 6.1 | 3.3 | DMAMP | 5.00 |
| | | | | acid | | | | | |
| Comparative | Benzyladenine | 0.001 | 2.0 | — | — | — | — | DMAMP | 0.05 |
| Example 1 | | | | | | | | | |
| Comparative | Benzyladenine | 0.001 | 1.8 | Acetic | 0.0033 | 6.1 | 3.3 | DMAMP | 0.05 |
| Example 2 | | | | acid | | | | | |
| Comparative | Benzyladenine | 0.001 | 1.8 | Phosphoric | 0.0033 | 6.1 | 3.3 | DMAMP | 0.05 |
| Example 3 | | | | acid | | | | | |
| Comparative | Benzyladenine | 0.0003 | 0.4 | Sulfuric | 0.032 | 38.9 | 106.7 | DMAMP | 0.05 |
| Example 4 | | | | acid | | | | | |
| Comparative | Benzyladenine | 0.0003 | 0.6 | DBS | 0.0001 | 0.2 | 0.3 | DMAMP | 0.05 |
| Example 5 | | | | | | | | | |

| | Semiconductor treatment liquid | | | | | | | |
|---|---|---|---|---|---|---|---|---|
| | | Additive | | | Object | | | |
| | | | Content | | Anticorrosion | | Defect | |
| | | | (% by | | properties | | removability | |
| | (B)/(C) | Type | mass) | pH | Cu | Co | Cu | Co |
| Example 39 | 0.066 | — | — | 10.9 | A | A | A | A |
| Example 40 | 0.066 | — | — | 11.0 | A | A | A | A |
| Example 41 | 0.066 | — | — | 10.9 | B | B | B | B |
| Example 42 | 0.066 | — | — | 10.9 | B | B | B | B |
| Example 43 | 0.066 | — | — | 10.9 | A | A | A | A |
| Example 44 | 0.066 | Succinic | 0.001 | 10.9 | A | A | A | A |
| | | acid | | | | | | |
| Example 45 | 0.066 | Tartaric | 0.001 | 10.9 | A | A | A | A |
| | | acid | | | | | | |
| Example 46 | 0.066 | Maleic | 0.001 | 10.9 | A | A | A | A |
| | | acid | | | | | | |
| Example 47 | 0.066 | Poly- | 0.001 | 10.9 | A | A | A | A |
| | | acrylic | | | | | | |
| | | acid | | | | | | |
| Example 48 | 0.066 | IPA | 0.10 | 10.9 | A | A | A | A |
| | | EGBE | 0.10 | | | | | |
| Example 49 | 0.066 | EGBE | 5.0 | 10.9 | A | A | A | A |
| Example 50 | 0.066 | — | — | 12.0 | A | A | A | A |
| Comparative | — | — | — | 11.1 | A | A | D | D |
| Example 1 | | | | | | | | |
| Comparative | 0.066 | — | — | 10.9 | B | C | D | D |
| Example 2 | | | | | | | | |
| Comparative | 0.066 | — | — | 10.9 | B | D | D | D |
| Example 3 | | | | | | | | |
| Comparative | 0.640 | — | — | 3.1 | D | D | D | D |
| Example 4 | | | | | | | | |
| Comparative | 0.002 | — | — | 11.1 | B | C | D | D |
| Example 5 | | | | | | | | |

From the above tables, it was found that the treatment liquid according to the embodiment of the present invention had excellent anticorrosion properties against Cu and Co, and defects were unlikely to remain on the surface of the object to be treated after cleaning the object to be treated with water, which contained Cu or Co.

From the comparison of Examples 1 to 7, it was found that, in a case where the purine compound included at least one selected from the group consisting of adenine, xanthine, hypoxanthine, guanine, adenosine, and benzyladenine, the anticorrosion properties were more excellent; and in a case where the purine compound included at least one selected from the group consisting of adenine and xanthine, the defect removability was more excellent.

From the comparison of Examples 1 and 13 to 19, it was found that, in a case where the mass ratio ((B)/(A)) of the content of the specific compound to the content of the purine compound was 0.5 to 20.0, the anticorrosion properties and the defect removability were more excellent; and in a case where the mass ratio ((B)/(A)) was 1.0 to 10.0, the anticorrosion properties and the defect removability were more excellent.

From the comparison of Examples 1 and 20 to 22, it was found that, in a case where the content of the purine compound was 0.0001% to 0.008% by mass with respect to the total mass of the treatment liquid, the defect removability was more excellent.

From the comparison of Examples 1 and 20 to 22, it was found that, in a case where the content of the purine compound was 0.1% to 10.0% by mass with respect to the total mass of components in the treatment liquid excluding a solvent, the anticorrosion properties and the defect removability were more excellent.

From the comparison of Examples 1 and 13 to 19, it was found that, in a case where the content of the specific compound was 0.0001% to 0.015% by mass with respect to the total mass of the treatment liquid, the anticorrosion properties were more excellent; and in a case where the content of the specific compound was 0.001% to 0.01% by mass, the anticorrosion properties and the defect removability were more excellent.

From the comparison of Examples 1 and 13 to 19, it was found that, in a case where the content of the specific compound was 0.5% to 20.0% by mass with respect to the total mass of components in the treatment liquid excluding a solvent, the anticorrosion properties were more excellent; and in a case where the content of the specific compound was 0.8% to 15.0% by mass with respect to the total mass of components in the treatment liquid excluding a solvent, the anticorrosion properties and the defect removability were more excellent.

From the comparison of Examples 16 to 19, it was found that, in a case where the pH was 10.0 to 13.5, the defect removability was more excellent; and in a case where the pH was 10.5 to 13.0, the anticorrosion properties were more excellent.

From the comparison of Examples 1 and 13 to 22, it was found that, in a case where the mass ratio ((B)/(C)) of the content of the specific compound to the content of the amine compound was 0.01 to 0.40, the anticorrosion properties were more excellent. In addition, it was found that, in a case where the mass ratio ((B)/(C)) of the content of the specific compound to the content of the amine compound was 0.02 to 0.20, the defect removability was more excellent.

From the comparison of Examples 1 to 4 and 31 to 37, it was found that, in a case where two or more kinds of amine compounds were used in combination, the defect removability was more excellent.

From the comparison of Examples 1, 4, and 34, it was found that, in a case where two or more kinds of purine compounds were used in combination, the defect removability was more excellent.

From the results of Examples 1, 23 to 38, and 41 to 43, it was found that, in a case where the treatment liquid contained at least one selected from the group consisting of a tertiary amine compound and a quaternary ammonium compound, the anticorrosion properties and the defect removability were more excellent.

From the results of Examples 1 and 50, it was found that the effect of the present invention was excellent even in a case where the concentration of the treatment liquid was different.

Furthermore, the treatment liquid described in Example 50 was diluted 50 times in terms of mass ratio with ultrapure water as a diluent. In a case where the same evaluations as in Example 50 were performed according to the above-described evaluation procedures using the obtained diluted treatment liquid, the same evaluation results as in Example 50 were obtained.

[Evaluation 2 of Treatment Liquid: Semiconductor Substrate after Buffing Cleaning]

A wafer (diameter: 12 inches) having a Cu film or a Co film on a surface was polished according to the procedure described in [Evaluation of defect removability] of [Evaluation 1 of treatment liquid: semiconductor substrate after CMP].

The polished surface of the wafer subjected to the CMP treatment was subjected to buffing cleaning under the following conditions using FREX300S-II (polishing device, manufactured by EBARA CORPORATION).
Table rotation speed: 80 rpm
Head rotation speed: 78 rpm
In-plane average value of polishing pressure: 138 hPa
Polishing pad: IC1400 manufactured by Rodel-Nitta
Cleaning liquid: treatment liquid used in Example 1
Supply rate of cleaning liquid: 250 mL/min
Polishing time: 20 seconds

The obtained wafer subjected to the buffing cleaning was subjected to scrub cleaning for 1 minute using the treatment liquid used in Example 1, adjusted to room temperature (23° C.), washed with DI water for 30 seconds, and then subjected to a drying treatment. Thereafter, as a result of obtaining the number of defects based on residues on the polished surface of the wafer according to the procedure described in the evaluation of the defect removability of the evaluation 1, the same evaluation results as in Example 1 were obtained.

Even in a case where the treatment liquids used in Examples 2 to 50 were used instead of the above-described treatment liquid used in Example 1, the same evaluation results as the results of each of Examples shown in Tables 1 to 3 described above were obtained.

Furthermore, even in a case where a diluted treatment liquid obtained by diluting the treatment liquid used in Example 50 by 50 times in terms of mass ratio was used instead of the above-described treatment liquid used in Example 1, the same evaluation results as in Example 50 were obtained.

What is claimed is:

1. A semiconductor treatment liquid comprising:
at least one purine compound selected from the group consisting of purine and a purine derivative;
at least one specific compound selected from the group consisting of an organic sulfonic acid compound having 10 or less carbon atoms, sulfuric acid, and a salt of these compounds; and
water,
wherein a pH is more than 7.0.

2. The semiconductor treatment liquid according to claim 1,
wherein the specific compound includes at least one selected from the group consisting of sulfuric acid, methanesulfonic acid, ethanesulfonic acid, 1,2-ethanedisulfonic acid, benzenesulfonic acid, paratoluenesulfonic acid, and a salt of these compounds.

3. The semiconductor treatment liquid according to claim 1,
wherein a content of the specific compound is 0.1% to 40.0% by mass with respect to a total mass of components in the treatment liquid excluding a solvent.

4. The semiconductor treatment liquid according to claim 1,
wherein a mass ratio of a content of the specific compound to a content of the purine compound is 0.01 to 100.0.

5. The semiconductor treatment liquid according to claim 1,
wherein a pKa of the specific compound is 2.0 or less.

6. The semiconductor treatment liquid according to claim 1, further comprising:
an amine compound.

7. The semiconductor treatment liquid according to claim 6,
wherein the amine compound includes at least one selected from the group consisting of a quaternary ammonium compound and a tertiary amine compound.

8. The semiconductor treatment liquid according to claim 6,
wherein the amine compound is a tertiary amine compound.

9. The semiconductor treatment liquid according to claim 6,
wherein the amine compound has two or more nitrogen atoms.

10. The semiconductor treatment liquid according to claim 6,
wherein the semiconductor treatment liquid contains two or more amine compounds.

11. The semiconductor treatment liquid according to claim 1,
wherein a pH is 9.0 to 14.0.

12. The semiconductor treatment liquid according to claim 1,
wherein the purine compound includes at least one selected from the group consisting of adenine, xanthine, guanine, adenosine, hypoxanthine, and benzyladenine.

13. The semiconductor treatment liquid according to claim 1,
wherein the semiconductor treatment liquid is used as a cleaning liquid.

14. The semiconductor treatment liquid according to claim 1,
wherein the semiconductor treatment liquid is used for an object which has been subjected to a chemical mechanical polishing treatment.

15. The semiconductor treatment liquid according to claim 1,
wherein the semiconductor treatment liquid is used for an object containing at least one metal selected from the group consisting of Cu and Co.

16. The semiconductor treatment liquid according to claim 1,
wherein the semiconductor treatment liquid is used for an object containing at least one metal selected from the group consisting of Cu and Co, which has been subjected to a chemical mechanical polishing treatment.

17. A treatment method for an object to be treated, comprising:
a step of bringing an object containing at least one metal selected from the group consisting of Cu and Co, which has been subjected to a chemical mechanical polishing treatment, into contact with the semiconductor treatment liquid according to claim 1.

18. A manufacturing method of an electronic device, comprising:
the treatment method for an object to be treated according to claim 17.

19. The semiconductor treatment liquid according to claim 2,
wherein a content of the specific compound is 0.1% to 40.0% by mass with respect to a total mass of components in the treatment liquid excluding a solvent.

20. The semiconductor treatment liquid according to claim 2,
wherein a mass ratio of a content of the specific compound to a content of the purine compound is 0.01 to 100.0.
